(19) United States
(12) Patent Application Publication
(10) Pub. No.: US 2024/0333236 A1
(43) Pub. Date: Oct. 3, 2024

(54) ANALOG ET CIRCUIT, RADIO-FREQUENCY SYSTEM, COMMUNICATION DEVICE, AND VOLTAGE SUPPLY METHOD

(71) Applicant: Murata Manufacturing Co., Ltd., Nagaokakyo-shi (JP)

(72) Inventors: Kazuto HIRAI, Nagaokakyo-shi (JP); Kouji YAMAGUCHI, Nagaokakyo-shi (JP); Muneharu KATO, Nagaokakyo-shi (JP); Sho OKAMOTO, Nagaokakyo-shi (JP)

(21) Appl. No.: 18/611,829

(22) Filed: Mar. 21, 2024

(30) Foreign Application Priority Data
Mar. 27, 2023 (JP) 2023-049989

(51) Int. Cl. H03F 3/213

(52) U.S. Cl. CPC H03F 3/213; H03F 2200/102; H03F 2200/451

(57) ABSTRACT

An analog ET circuit is provided that includes an envelope amplifier and a voltage supply unit. The voltage supply unit is configured to supply plural discrete voltages to the envelope amplifier. The envelope amplifier is configured to receive an envelope signal and the plural discrete voltages and output a continuous output voltage.

### CROSS REFERENCE TO RELATED APPLICATIONS

This application claims priority to Japanese Patent Application No. 2023-049989, filed Mar. 27, 2023, the entire content of which is hereby incorporated by reference in its entirety.

### TECHNICAL FIELD

The present disclosure generally relates to an analog ET circuit, a radio-frequency (RF) system, a communication device, and a voltage supply method, and more specifically, to an analog ET circuit including an envelope amplifier, a radio-frequency system including the analog ET circuit, a communication device including the radio-frequency system, and a voltage supply method.

### BACKGOUND

U.S. Patent Application Publication No. 2009/0191826 (hereinafter “Patent Document 1”) discloses an analog ET circuit that includes a combination of a switching power supply and a linear amplifier (e.g., an envelope amplifier).

In the analog ET circuit described in Patent Document 1, the switching power supply is directly coupled to a power amplifier, causing switching noise leakage. As a result, the loss of the envelope amplifier is significant.

### SUMMARY OF THE INVENTION

In view of the foregoing, the current disclosure provides an analog ET circuit, a radio-frequency system, a communication device, and a voltage supply method that reduces loss of the envelope amplifier.

In an exemplary aspect, an analog ET circuit is provided that includes an envelope amplifier and a voltage supply unit. The voltage supply unit is configured to supply a plurality of discrete voltages to the envelope amplifier. The envelope amplifier is configured to receive an envelope signal and the plurality of discrete voltages and output a continuous output voltage.

In another exemplary aspect, an analog ET circuit is provided that includes an envelope amplifier and a voltage supply unit. The voltage supply unit is configured to supply a plurality of discrete voltages to the envelope amplifier. The envelope amplifier includes an input terminal receiving an envelope signal, an output terminal outputting a continuous output voltage, and a power supply terminal supplied with the plurality of discrete voltages.

In another exemplary aspect, a radio-frequency system is provided that includes the analog ET circuit and a power amplifier coupled to the analog ET circuit.

Furthermore, a communication device is provided in an exemplary aspect that includes the radio-frequency system and a signal processing circuit coupled to the radio-frequency system.

Moreover, a voltage supply method according to an exemplary aspect is provided that includes generating a plurality of discrete voltages in advance, and receiving an envelope signal and the plurality of discrete voltages to output a continuous output voltage.

According to the analog ET circuit, radio-frequency system, communication device, and voltage supply method according to the aforementioned aspects of the present disclosure, loss of the envelope amplifier is reduced.

### BRIEF DESCRIPTION OF THE DRAWINGS

FIG. 1 is a circuit diagram of an analog ET circuit according to exemplary Embodiment 1;

FIG. 2 is a block diagram of a communication device according to exemplary Embodiment 1;

FIG. 3 is a waveform diagram of analog ET;

FIG. 4 is a circuit diagram of a voltage supply unit of the analog ET circuit according to exemplary Embodiment 1;

FIG. 5 is a block diagram of a digital control circuit according to exemplary Embodiment 1;

FIG. 6 is a circuit diagram of an analog ET circuit according to exemplary Embodiment 2;

FIG. 7 is a circuit diagram of an analog ET circuit according to exemplary Embodiment 3;

FIG. 8 is a circuit diagram of an analog ET circuit according to exemplary Embodiment 4;

FIG. 9 is a circuit diagram of an analog ET circuit according to exemplary Embodiment 5;

FIG. 10 is a waveform diagram of analog ET;

FIG. 11 is a circuit diagram of an analog ET circuit according to exemplary Embodiment 6;

FIG. 12 is a circuit diagram of an analog ET circuit according to exemplary Embodiment 7;

FIG. 13 is a circuit diagram of an analog ET circuit according to exemplary Embodiment 8;

FIG. 14 is a circuit diagram of an analog ET circuit according to exemplary Embodiment 9; and

FIG. 15 is an explanatory view explaining control using DCL.

### DETAILED DESCRIPTION

Exemplary embodiments 1 to 9 of the present disclosure will be described below with reference to the drawings. It is noted that the drawings referred to in the following embodiments and the like are schematic, and sizes and thicknesses of constituent elements in the drawings do not always reflect actual dimensions. Size and thickness ratios also do not always reflect actual dimensional ratios.

### EXEMPLARY EMBODIMENT 1

### 1. Analog ET Circuit

An analog ET circuit 1 according to Embodiment 1 will be described with reference to the drawings.

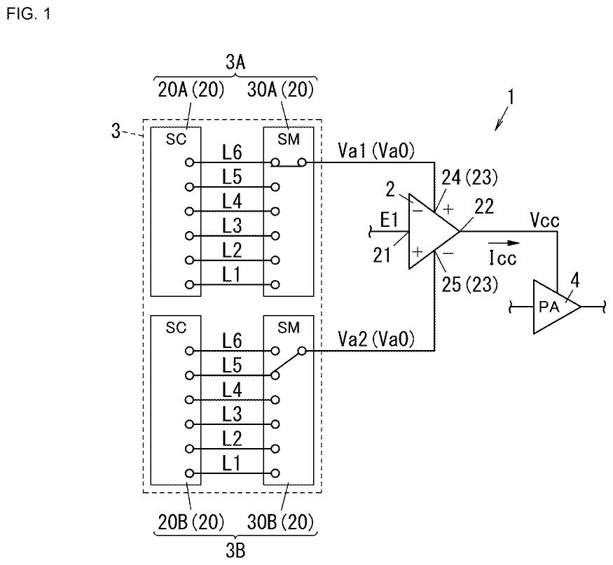

As illustrated in FIG. 1, the analog ET circuit 1 according to Embodiment 1 includes an envelope amplifier 2 and a voltage supply unit 3. The voltage supply unit 3 is configured to supply plural discrete voltages Va0 to the envelope amplifier 2. The envelope amplifier 2 is configured to receive an envelope signal E1 and the plural discrete voltages Va0 and output a continuous output voltage Vcc.

The discrete voltages Va0 to be supplied to the envelope amplifier 2 can thereby be switched depending on the voltage of the envelope signal E1 to be received by the envelope amplifier 2. This configuration reduces the loss of the envelope amplifier 2.

Furthermore, no switching element is directly coupled to an element (for example, a power amplifier 4) on the output side of the analog ET circuit 1. Accordingly, this configuration reduces switching noise leakage to elements on the output side of the analog ET circuit 1.

### 2. Circuit Configuration of Analog ET Circuit, Radio-Frequency System, and Communication Device

Hereinafter, circuit configurations of the analog ET circuit 1, a radio-frequency system 200, and a communication device 9 according to Embodiment 1 will be described with reference to the drawings.

### 2.1. Circuit Configuration of Radio-Frequency System

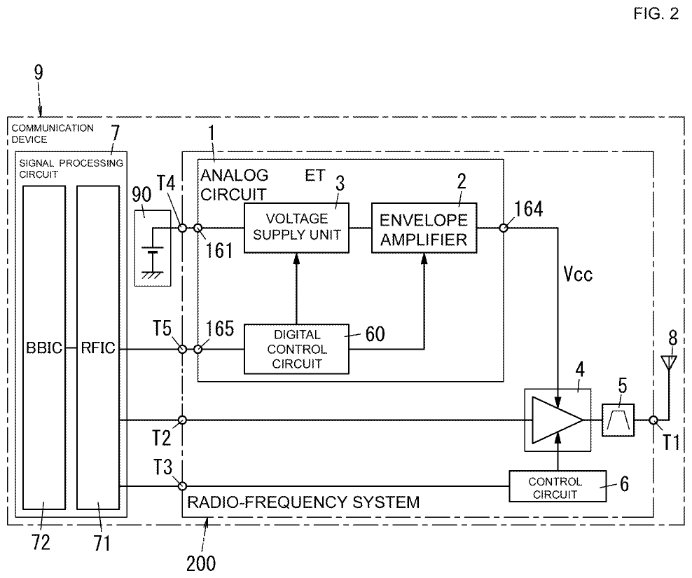

As illustrated in FIG. 2, the radio-frequency system 200 includes the analog ET circuit 1, the power amplifier 4, a filter 5, a control circuit 6, and plural external connection terminals. The power amplifier 4 is coupled to the analog ET circuit 1. The plural external connection terminals include an antenna terminal T1, a signal input terminal T2, a first control terminal T3, a power supply connection terminal T4, and four second control terminals T5 (only one second control terminal T5 is illustrated in FIG. 2).

The analog ET circuit 1 is a circuit configured to supply the continuous output voltage Vcc to the power amplifier 4 based on the envelope signal E1.

The communication device 9, which includes the analog ET circuit 1 and the power amplifier 4, uses analog envelope tracking (hereinafter, referred to as analog ET) to amplify a radio-frequency (RF) signal in the power amplifier 4.

Analog ET is a method of tracking the envelope of a radio-frequency signal by using continuous voltage levels. The mode in which analog ET is applied to generation of the output voltage Vcc is referred to as an analog ET mode.

For purposes of this disclosure, a frame represents a unit forming a radio-frequency signal. For example, in 5-th generation New Radio (5G NR) and Long-Term Evolution (LTE®), a frame includes ten subframes, and each subframe includes plural slots. Each slot includes plural symbols. Each subframe is 1 ms long, and each frame is 10 ms long.

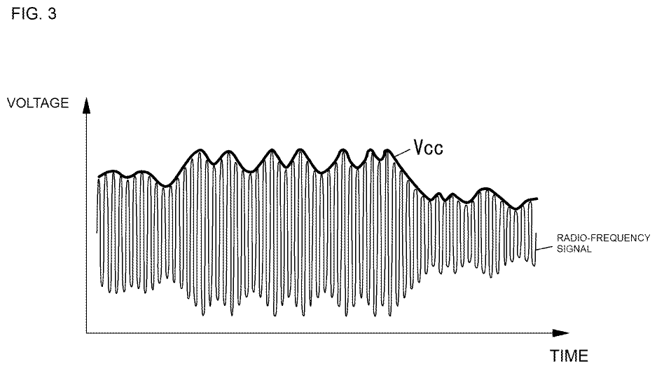

Herein, the analog ET mode will be described with reference to FIG. 3.

As illustrated in FIG. 3, in the analog ET mode, the output voltage Vcc is continuously varied to track the envelope of the modulated signal. In the analog ET mode, the output voltage Vcc easily follows changes in the envelope of the radio-frequency signal when the channel bandwidth is narrow (e.g., the channel bandwidth is less than 60 MHz, for example), but is less likely to easily follow changes in the envelope of the radio-frequency signal when the channel bandwidth is wide (the channel bandwidth is not less than 60 MHz). In other words, when the channel bandwidth is wide, changes in amplitude of the output voltage Vcc tend to lag changes in the envelope of the radio-frequency signal.

As illustrated in FIG. 2, the analog ET circuit 1 includes the envelope amplifier 2 and the voltage supply unit 3.

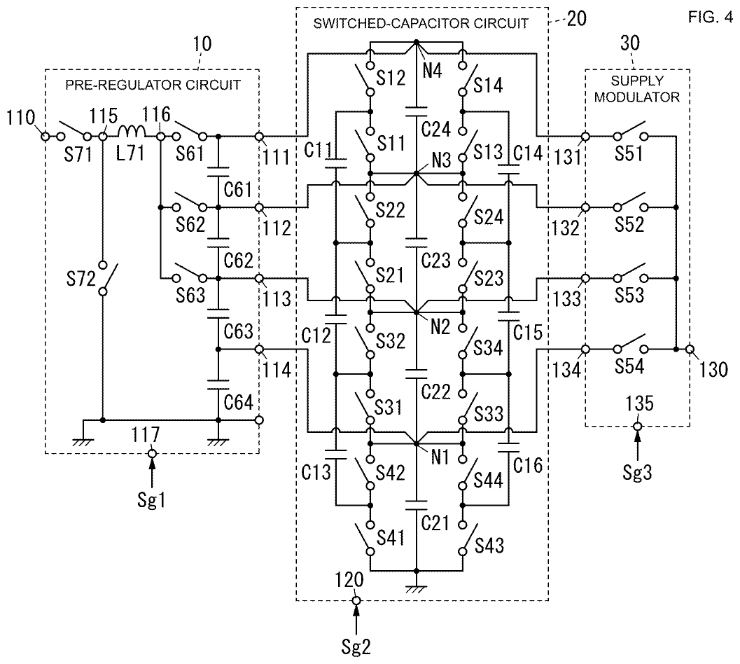

As illustrated in FIG. 4, the voltage supply unit 3 includes a pre-regulator circuit 10, a switched-capacitor circuit 20, and a supply modulator 30.

The pre-regulator circuit 10 is, for example, a direct current (DC)-DC converter that is configured to convert a direct-current voltage (e.g., a first voltage) supplied from a direct-current power source 90, which is included in the communication device 9, into a second voltage. The pre-regulator circuit 10 is configured to perform a step-up operation so that the voltage value of the second voltage be greater than that of the first voltage and perform a step-down operation so that the voltage value of the second voltage be smaller than that of the first voltage. That is, the pre-regulator circuit 10 is a buck-boost DC-DC converter.

The switched-capacitor circuit 20 is configured to receive the second voltage from the pre-regulator circuit 10 as an input voltage and generate plural discrete voltages (e.g., a plurality of third voltages). The plural discrete voltages have different voltage levels. The switched-capacitor circuit 20 is sometimes referred to as a switched-capacitor voltage balancer.

The supply modulator 30 is configured to, based on an analog control signal corresponding to the envelope signal E1, selectively output to the envelope amplifier 2, at least one of the plural discrete voltages (e.g., the plurality of third voltages) generated by the switched-capacitor circuit 20. The supply modulator 30 outputs at least one discrete voltage selected from the plural discrete voltages. In the analog ET circuit 1, the supply modulator 30 is configured to repeatedly perform the selection of the discrete voltages over time to change the voltage level of the output voltage of the supply modulator 30 over time. The analog ET circuit 1 is therefore configured to change over time, the voltage level of the output voltage Vcc to be supplied to the power amplifier 4.

The power amplifier 4 includes an input terminal, an output terminal, a power supply terminal, and a control terminal. The input terminal of the power amplifier 4 is coupled to a signal processing circuit 7 of the communication device 9 through the signal input terminal T2. The output terminal of the power amplifier 4 is coupled to an antenna 8 of the communication device 9 with the filter 5 and the antenna terminal T1 interposed therebetween. The power amplifier 4 amplifies a radio-frequency transmission signal (hereinafter, referred to as a transmission signal) in a predetermined band that is outputted from the signal processing circuit 7 and outputs the amplified radio-frequency transmission signal.

As further shown, the filter 5 is coupled between the output terminal of the power amplifier 4 and the antenna terminal T1. The filter 5 has a pass band including the range of frequencies of the predetermined band. The filter 5 is thereby configured to pass the transmission signal in the predetermined band that is amplified by the power amplifier 4. In the radio-frequency system 200, the transmission signal outputted from the power amplifier 4 is outputted to the antenna 8 through the filter 5 and the antenna terminal T1.

The control circuit 6 is coupled to an RF signal processing circuit 71 of the signal processing circuit 7 through the first control terminal T3. The control circuit 6 is also coupled to the control terminal of the power amplifier 4. The control circuit 6 receives a control signal from the RF signal processing circuit 71 of the signal processing circuit 7 and thereby is configured to control the magnitude and the supply timing of bias current (or bias voltage) to be supplied to the control terminal of the power amplifier 4.

### 2.2. Circuit Configuration of Communication Device

As illustrated in FIG. 2, the communication device 9 includes the radio-frequency system 200, the signal processing circuit 7, the antenna 8, and the direct-current power source 90. The signal processing circuit 7 is coupled to the radio-frequency system 200.

The direct-current power source 90 is a rechargeable battery, for example. The direct-current power source 90 is not limited to a rechargeable battery and may be another battery.

The antenna 8 transmits the transmission signal in the predetermined band outputted from the antenna terminal T1.

The signal processing circuit 7 includes the RF signal processing circuit 71 and a baseband signal processing circuit 72. The RF signal processing circuit 71 is a radio frequency integrated circuit (RFIC), for example and performs signal processing for radio-frequency signals. For example, the RF signal processing circuit 71 performs signal processing, such as up convert, for a radio-frequency signal (e.g., a transmission signal) outputted from the baseband signal processing circuit 72 and outputs the radio-frequency signal obtained through the signal processing. The baseband signal processing circuit 72 is a baseband Integrated circuit (BBIC), for example. The baseband signal processing circuit 72 generates an I-phase signal and a Q-phase signal from a baseband signal. The baseband signal is an audio signal or an image signal inputted from the outside, for example. The baseband signal processing circuit 72 combines the I-phase signal and the Q-phase signal for IQ modulation processing and outputs a transmission signal. In this process, the transmission signal is generated as a modulated signal (e.g., an IQ signal) obtained by amplitude-modulating a carrier signal having a predetermined frequency with a period longer than the period of the carrier signal.

Based on the envelope signal E1 of the radio-frequency signal received from the baseband signal processing circuit 72, the RF signal processing circuit 71 causes the supply modulator 30 to select the voltage level of the output voltage Vcc to be used in the power amplifier 4 from the voltage levels of the plural discrete voltages generated by the switched-capacitor circuit 20. The analog ET circuit 1 thereby outputs the output voltage Vcc based on analog envelope tracking (ET). The envelope signal E1 is a signal representing an envelope of the radio-frequency signal (i.e., the modulated signal). The envelope value is (I²+Q²)^{1/2}, for example. Herein, (I, Q) indicates a constellation point. The constellation point is a point on a constellation diagram and indicates a signal modulated by digital modulation. (I, Q) is determined by the baseband signal processing circuit 72 based on, for example, transmission information.

2.3. Circuit Configuration of Analog ET circuit

As illustrated in FIG. 2, the analog ET circuit 1 includes the envelope amplifier 2, the voltage supply unit 3, and a digital control circuit 60.

### 2.4. Envelope Amplifier

The envelope amplifier 2 is configured to receive the envelope signal E1 and the plural discrete voltages Va0 and output the continuous output voltage Vcc as illustrated in FIG. 1. The envelope amplifier 2 is a linear amplifier, for example.

In Embodiment 1, the envelope amplifier 2 is configured to receive the envelope signal E1, plural first discrete voltages Va1, and plural second discrete voltages Va2 and output the continuous output voltage Vcc.

The envelope amplifier 2 includes an input terminal 21, an output terminal 22, and plural (two in the example in FIG. 1) power supply terminals 23. The input terminal 21 is a terminal receiving the envelope signal E1. The output terminal 22 is a terminal outputting the continuous output voltage Vcc. The plural power supply terminals 23 are terminals supplied with the supply discrete voltages Va0. In other words, the plural power supply terminals 23 are terminals supplied with power supply voltages to operate the envelope amplifier 2.

The plural power supply terminals 23 include a plus power supply terminal (e.g., a first power supply terminal) 24 and a minus power supply terminal (e.g., a second power supply terminal) 25. The plus power supply terminal 24 is a terminal supplied with the plural first discrete voltages Va1. The plus power supply terminal 24 is a terminal supplied with the voltages Va1 having high voltage levels. The minus power supply terminal 25 is a terminal supplied with the plural second discrete voltages Va2. The minus power supply terminal 25 is a terminal supplied with the voltages Va2 having low voltage levels. That is, the voltages Va2 supplied to the minus power supply terminal 25 are lower than the voltages Va1 supplied to the plus power supply terminal 24.

### 2.5. Voltage Supply Unit

The voltage supply unit 3 is configured to supply the plural discrete voltage Va0 to the envelope amplifier 2. The voltage supply unit 3 includes a first voltage supply unit 3A and a second voltage supply unit 3B.

As shown, the first voltage supply unit 3A includes a first switched-capacitor circuit 20A and a first supply modulator 30A. The first voltage supply unit 3A outputs the first discrete voltage Va1 that has a voltage level Ln to the envelope amplifier 2. The first voltage supply unit 3A is configured to supply the plural first discrete voltages Va1 to the plus power supply terminal 24 (the high side) of the envelope amplifier 2. The first switched-capacitor circuit 20A is configured to generate plural discrete voltages depending on input voltage. The first supply modulator 30A is configured to selectively output one of the plural discrete voltages to the envelope amplifier 2.

The second voltage supply unit 3B is configured to supply the plural second discrete voltages Va2 to the minus power supply terminal 25 (the low side) of the envelope amplifier 2. The second voltage supply unit 3B includes a second switched-capacitor circuit 20B and a second supply modulator 30B. The second voltage supply unit 3B outputs the second discrete voltage Va2 that has a voltage level Ln-1 to the envelope amplifier 2. The second switched-capacitor circuit 20B is configured to generate plural discrete voltages depending on input voltage. The second supply modulator 30B is configured to selectively output one of the plural discrete voltages to the envelope amplifier 2.

Each of the first and second voltage supply units 3A and 3B includes the pre-regulator circuit 10, the switched-capacitor circuit 20, and the supply modulator 30 as illustrated in FIG. 4.

### 2.6. Pre-regulator Circuit

As illustrated in FIG. 4, the pre-regulator circuit 10 includes an input terminal 110, plural (four in the example in FIG. 4) output terminals 111 to 114, plural inductor connection terminals 115 and 116, a control terminal 117, plural (five in the example in FIG. 4) switches S61, S62, S63, S71, and S72, a power inductor L71, and plural (four in the example in FIG. 4) capacitors C61, C62, C63, and C64. The power inductor L71 is an inductor used to step up and/or step down (step up, step down, or step up and down) direct-current voltage.

The input terminal 110 is an input terminal for direct-current voltage. That is, the input terminal 110 is a terminal receiving input voltage from the direct-current power source 90 (see FIG. 2).

The output terminal 111 is an output terminal for a voltage V4. That is, the output terminal 111 is a terminal supplying the voltage V4 to the switched-capacitor circuit 20. The output terminal 111 is coupled to a node N4 of the switched-capacitor circuit 20.

The output terminal 112 is an output terminal for a voltage V3. That is, the output terminal 112 is a terminal supplying the voltage V3 to the switched-capacitor circuit 20. The output terminal 112 is coupled to a node N3 of the switched-capacitor circuit 20.

The output terminal 113 is an output terminal for a voltage V2. That is, the output terminal 113 is a terminal supplying the voltage V2 to the switched-capacitor circuit 20. The output terminal 113 is coupled to a node N2 of the switched-capacitor circuit 20.

The output terminal 114 is an output terminal for a voltage V1. That is, the output terminal 114 is a terminal supplying the voltage V1 to the switched-capacitor circuit 20. The output terminal 114 is coupled to a node N1 of the switched-capacitor circuit 20.

The inductor connection terminal 115 is coupled to one end (e.g., a first end) of the power inductor L71. The inductor connection terminal 116 is coupled to the other end (e.g., a second end) of the power inductor L71.

The control terminal 117 is an input terminal for a control signal Sg1. That is, the control terminal 117 is a terminal receiving the control signal Sg1 for controlling the pre-regulator circuit 10. The control signal Sg1 is a signal for controlling on/off of the plural switches S61 to S63, S71, and S72, which are included in the pre-regulator circuit 10.

The switch S71 is coupled between the input terminal 110 and the one end (e.g., the first end) of the power inductor L71. Specifically, the switch S71 has a first terminal coupled to the input terminal 110 and a second terminal coupled to the one end (e.g., the first end) of the power inductor L71 through the inductor connection terminal 115. In the above-described connection configuration, the switch S71 is switched on and off to switch connection and non-connection between the input terminal 110 and the one end of the power inductor L71.

The switch S72 is coupled to the one end (e.g., the first end) of the power inductor L71 and ground. Specifically, the switch S72 has a first terminal coupled to the one end (e.g., the first end) of the power inductor L71 through the inductor connection terminal 115 and a second terminal coupled to the ground. In the above-described connection configuration, the switch S72 is switched on and off to switch connection and non-connection between the one end of the power inductor L71 and the ground.

The switch S61 is coupled between the other end (e.g., the second end) (e.g., the second end) of the power inductor L71 and the output terminal 111. Specifically, the switch S61 has a first terminal coupled to the other end (e.g., the second end) of the power inductor L71 and a second terminal coupled to the output terminal 111. In the above-described connection configuration, the switch S61 is switched on and off to switch connection and non-connection between the other end of the power inductor L71 and the output terminal 111.

The switch S62 is coupled between the other end (e.g., the second end) of the power inductor L71 and the output terminal 112. Specifically, the switch S62 has a first terminal coupled to the other end (e.g., the second end) of the power inductor L71 and a second terminal coupled to the output terminal 112. In the above-described connection configuration, the switch S62 is switched on and off to switch connection and non-connection between the other end of the power inductor L71 and the output terminal 112.

The switch S63 is coupled between the other end (e.g., the second end) of the power inductor L71 and the output terminal 113. Specifically, the switch S63 has a first terminal coupled to the other end (e.g., the second end) of the power inductor L71 and a second terminal coupled to the output terminal 113. In the above-described connection configuration, the switch S63 is switched on and off to switch connection and non-connection between the other end of the power inductor L71 and the output terminal 113.

The capacitor C61 is coupled between the output terminal 111 and the output terminal 112. The one of the two electrodes of the capacitor C61 is coupled to the switch S61 and the output terminal 111, and the other electrode of the capacitor C61 is coupled to the switch S62, the output terminal 112, and one of the two electrodes of the capacitor C62.

The capacitor C62 is coupled between the output terminal 112 and the output terminal 113. The one of the two electrodes of the capacitor C62 is coupled to the switch S62, the output terminal 112, and the other electrode of the capacitor C61, and the other electrode of the capacitor C62 is coupled to the switch S63, the output terminal 113, and one of the two electrodes of the capacitor C63.

The capacitor C63 is coupled between the output terminal 113 and the output terminal 114. The one of the two electrodes of the capacitor C63 is coupled to the switch S63, the output terminal 113, and the other electrode of the capacitor C62, and the other electrode of the capacitor C63 is coupled to the output terminal 114 and one of the two electrodes of the capacitor C64.

The capacitor C64 is coupled between the output terminal 114 and the ground. One of the two electrodes of the capacitor C64 is coupled to the output terminal 114 and the other electrode of the capacitor C63, and the other electrode of the capacitor C64 is coupled to the ground.

The plural switches S61 to S63 are controlled so as to be each exclusively turned on. That is, only one of the switches S61 to S63 is turned on while the others are turned off. The voltage levels of the voltages V1 to V4 are varied depending on which one of the switches S61 to S63 is turned on.

The pre-regulator circuit 10 configured as described above supplies electric charges to the switched-capacitor circuit 20 through at least one of the plural output terminals 111 to 113.

### 2.7. Switched-capacitor Circuit

As illustrated in FIG. 4, the switched-capacitor circuit 20 includes plural (six in the example in FIG. 4) capacitors C11 to C16, plural (four in the example in FIG. 4) capacitors C21 to C24, plural (16 in the example in FIG. 4) switches S11 to S14, S21 to S24, S31 to S34, S41 to S44, and a control terminal 120.

The control terminal 120 is an input terminal for a control signal Sg2 from the digital control circuit 60. The control signal Sg2 is a signal to control on/off of the plural switches S11 to S14, S21 to S24, S31 to S34, and S41 to S44, which are included in the switched-capacitor circuit 20.

The plural capacitors C11 to C16 individually serve as a flying capacitor (e.g., a transfer capacitor). Specifically, the plural capacitors C11 to C16 are individually used to step up or down the voltage (e.g., an input voltage) supplied from the pre-regulator circuit 10. More specifically, the plural capacitors C11 to C16 transfer electric charges between the capacitors C11 to C16 and the four nodes N1 to N4 so as to maintain the voltages V1 to V4 (the voltages relative to the ground potential) satisfying V1:V2:V3:V4=1:2:3:4 at the nodes N1 to N4. The plural voltages V1 to V4 correspond to the plural discrete voltages individually having plural discrete voltage levels. The voltage V1 is a voltage at the node N1; the voltage V2, at the node N2; the voltage V3, at the node N3; and the voltage V4, at the node N4.

The capacitor C11 has two electrodes. One of the two electrodes of the capacitor C11 is coupled to one end (e.g., a first end) of the switch S11 and one end (e.g., a first end) of the switch S12. The other electrode of the capacitor C11 is coupled to one end (e.g., a first end) of the switch S21 and one end (e.g., a first end) of the switch S22.

The capacitor C12 has two electrodes. One of the two electrodes of the capacitor C12 is coupled to the one end (e.g., the first end) of the switch S21 and the one end (e.g., the first end) of the switch S22. The other electrode of the capacitor C12 is coupled to one end (e.g., a first end) of the switch S31 and one end (e.g., a first end) of the switch S32.

In the switched-capacitor circuit 20, the capacitor C12 is an example of a first capacitor. The one of the two electrodes of the capacitor C12 serves as a first electrode of the first capacitor, and the other electrode of the capacitor C12 serves as a second electrode of the first capacitor.

The capacitor C13 has two electrodes. One of the two electrodes of the capacitor C13 is coupled to the one end (e.g., the first end) of the switch S31 and the one end (e.g., the first end) of the switch S32. The other electrode of the capacitor C13 is coupled to one end (e.g., a first end) of the switch S41 and one end (e.g., a first end) of the switch S42.

The capacitor C14 has two electrodes. One of the two electrodes of the capacitor C14 is coupled to one end (e.g., a first end) of the switch S13 and one end (e.g., a first end) of the switch S14. The other electrode of the capacitor C14 is coupled to one end (e.g., a first end) of the switch S23 and one end (e.g., a first end) of the switch S24.

The capacitor C15 has two electrodes. One of the two electrodes of the capacitor C15 is coupled to the one end (e.g., the first end) of the switch S23 and the one end (e.g., the first end) of the switch S24. The other electrode of the capacitor C15 is coupled to one end (e.g., a first end) of the switch S33 and one end (e.g., a first end) of the switch S34.

In the switched-capacitor circuit 20, the capacitor C15 is an example of a second capacitor. The one of the two electrodes of the capacitor C15 serves as a third electrode of the second capacitor, and the other electrode of the capacitor C15 serves as a fourth electrode of the second capacitor.

The capacitor C16 has two electrodes. One of the two electrodes of the capacitor C16 is coupled to the one end (e.g., the first end) of the switch S33 and the one end (e.g., the first end) of the switch S34. The other electrode of the capacitor C16 is coupled to one end (e.g., a first end) of the switch S43 and one end (e.g., a first end) of the switch S44.

A set of the capacitors C11 and C14, a set of the capacitors C12 and C15, and a set of the capacitors C13 and C16 individually can be complementarily charged and discharged by repetition of a first phase and a second phase.

In the first phase, the switches S12, S13, S22, S23, S32, S33, S42, and S43 are turned on. The one (the first electrode) of the two electrodes of the capacitor C12 (the first capacitor) is thereby coupled to the node N3; the other electrode (the second electrode) of the capacitor C12 and the one (the third electrode) of the two electrodes of the capacitor C15 (the second capacitor) are coupled to the node N2; and the other electrode (the fourth electrode) of the capacitor C15 is coupled to the node N1, for example.

In the second phase, the switches S11, S14, S21, S24, S31, S34, S41, and S44 are turned on. The one (the third electrode) of the two electrodes of the capacitor C15 (the second capacitor) is thereby coupled to the node N3; the other electrode (the fourth electrode) of the capacitor C15 (the second capacitor) and the one (the first electrode) of the two electrodes of the capacitor C12 (the first capacitor) are coupled to the node N2; and the other electrode (the second electrode) of the capacitor C12 (the first capacitor) is coupled to the node N1, for example.

As the first phase and the second phase are alternated, one of the capacitors C12 and C15 is being charged from the node N2 while the other capacitor C12 or C15 is being discharged to the capacitor C23, for example. That is, the capacitors C12 and C15 can be complementarily charged and discharged. The capacitors C12 and C15 are a pair of flying capacitors that are complementarily charged and discharged.

When the switches are switched as appropriate, the set of the capacitors C11 and C14 also serve as a pair of flying capacitors that are complementarily charged from a node and discharged to a smoothing capacitor similarly to the set of the capacitors C12 and C15. When the switches are switched as appropriate, the set of the capacitors C13 and C16 also serve as a pair of flying capacitors that are complementarily charged from a node and discharged to a smoothing capacitor similarly to the set of the capacitors C12 and C15.

The plural capacitors C21 to C24 each serve as a smoothing capacitor. That is, the capacitors C21 to C24 are individually used to hold and smooth the voltages V1 to V4 at the node N1 to N4, respectively.

The capacitor C21 is coupled between the node N1 and the ground. Specifically, one of the two electrodes of the capacitor C21 is coupled to the node N1. The other electrode (a sixth electrode) of the capacitor C21 is coupled to the ground.

The capacitor C22 is coupled between the node N2 and the node N1. Specifically, one of the two electrodes of the capacitor C22 is coupled to the node N2. The other electrode of the capacitor C22 is coupled to the node N1.

The capacitor C23 is coupled between the node N3 and the node N2. Specifically, one of the two electrodes of the capacitor C23 is coupled to the node N3. The other electrode of the capacitor C23 is coupled to the node N2.

The capacitor C24 is coupled between the node N4 and the node N3. Specifically, one of the two electrodes of the capacitor C24 is coupled to the node N4. The other electrode of the capacitor C24 is coupled to the node N3.

The switch S11 is coupled between one of the two electrodes of the capacitor C11 and the node N3. Specifically, the one end (e.g., the first end) of the switch S11 is coupled to one of the two electrodes of the capacitor C11. The other end (e.g., a second end) of the switch S11 is coupled to the node N3.

The switch S12 is coupled between the one of the two electrodes of the capacitor C11 and the node N4. Specifically, the one end (e.g., the first end) of the switch S12 is coupled to the one of the two electrodes of the capacitor C11. The other end (e.g., a second end) of the switch S12 is coupled to the node N4.

The switch S21 is coupled between the one (a first electrode) of the two electrodes of the capacitor C12 (the first capacitor) and the node N2. Specifically, the one end (e.g., the first end) of the switch S21 is coupled to the one (the first electrode) of the two electrodes of the capacitor C12 (the first capacitor) and the other electrode of the capacitor C11. The other end (e.g., a second end) of the switch S21 is coupled to the node N2. In the switched-capacitor circuit 20, the switch S21 is an example of a first switch.

The switch S22 is coupled between the one (the first electrode) of the two electrodes of the capacitor C12 and the node N3. Specifically, the one end (e.g., the first end) of the switch S22 is coupled to the one (the first electrode) of the two electrodes of the capacitor C12 and the other electrode of the capacitor C11. The other end (e.g., a second end) of the switch S22 is coupled to the node N3. In the switched-capacitor circuit 20, the switch S22 is an example of a third switch.

The switch S31 is coupled between the other electrode (the second electrode) of the capacitor C12 (the first capacitor) and the node N1. Specifically, the one end (e.g., the first end) of the switch S31 is coupled to the other electrode (the second electrode) of the capacitor C12 (the first capacitor) and the one of the two electrodes of the capacitor C13. The other end (e.g., a second end) of the switch S31 is coupled to the node N1. In the switched-capacitor circuit 20, the switch S31 is an example of a fourth switch.

The switch S32 is coupled between the other electrode (the second electrode) of the capacitor C12 (the first capacitor) and the node N2. Specifically, the one end (e.g., the first end) of the switch S32 is coupled to the other electrode (the second electrode) of the capacitor C12 and the one of the two electrodes of the capacitor C13. The other end (e.g., a second end) of the switch S32 is coupled to the node N2. That is, the other end (e.g., the second end) of the switch S32 is coupled to the other end (e.g., the second end) of the switch S21. In the switched-capacitor circuit 20, the switch S32 is an example of a second switch.

The switch S41 is coupled between the other electrode of the capacitor C13 and the ground. Specifically, the one end (e.g., the first end) of the switch S41 is coupled to the other electrode of the capacitor C13. The other end (e.g., a second end) of the switch S41 is coupled to the ground.

The switch S42 is coupled between the other electrode of the capacitor C13 and the node N1. Specifically, the one end (e.g., the first end) of the switch S42 is coupled to the other electrode of the capacitor C13. The other end (e.g., a second end) of the switch S42 is coupled to the node N1. That is, the other end (e.g., the second end) of the switch S42 is coupled to the other end (e.g., the second end) of the switch S31.

The switch S13 is coupled between the one of the two electrodes of the capacitor C14 and the node N3. Specifically, the one end (e.g., the first end) of the switch S13 is coupled to the one of the two electrodes of the capacitor C14. The other end (e.g., a second end) of the switch S13 is coupled to the node N3. That is, the other end (e.g., the second end) of the switch S13 is coupled to the other end (e.g., the second end) of the switch S11 and the other end (e.g., the second end) of the switch S22.

The switch S14 is coupled between the one of the two electrodes of the capacitor C14 and the node N4. Specifically, the one end (e.g., the first end) of the switch S14 is coupled to the one of the two electrodes of the capacitor C14. The other end (e.g., a second end) of the switch S14 is coupled to the node N4. That is, the other end (e.g., the second end) of the switch S14 is coupled to the other end (e.g., the second end) of the switch S12.

The switch S23 is coupled between the one (the third electrode) of the two electrodes of the capacitor C15 (the second capacitor) and the node N2. Specifically, the one end (e.g., the first end) of the switch S23 is coupled to the one (the third electrode) of the two electrodes of the capacitor C15 and the other electrode of the capacitor C14. The other end (e.g., a second end) of the switch S23 is coupled to the node N2. That is, the other end (e.g., the second end) of the switch S23 is coupled to the other end (e.g., the second end) of the switch S21 and the other end (e.g., the second end) of the switch S32. In the switched-capacitor circuit 20, the switch S23 is an example of a fifth switch.

The switch S24 is coupled between the one (the third electrode) of the two electrodes of the capacitor C15 (the second capacitor) and the node N3. Specifically, the one end (e.g., the first end) of the switch S24 is coupled to the one (the third electrode) of the two electrodes of the capacitor C15 and the other electrode of the capacitor C14. The other end (e.g., a second end) of the switch S24 is coupled to the node N3. That is, the other end (e.g., the second end) of the switch S24 is coupled to the other end (e.g., the second end) of the switch S11, the other end (e.g., the second end) of the switch S22, and the other end (e.g., the second end) of the switch S13. In the switched-capacitor circuit 20, the switch S24 is an example of a seventh switch.

The switch S33 is coupled between the other electrode of the capacitor C15 (the second capacitor) and the node N1. Specifically, the one end (e.g., the first end) of the switch S33 is coupled to the other electrode (the fourth electrode) of the capacitor C15 and the one of the two electrodes of the capacitor C16. The other end (e.g., a second end) of the switch S33 is coupled to the node N1. That is, the other end (e.g., the second end) of the switch S33 is coupled to the other end (e.g., the second end) of the switch S31 and the other end (e.g., the second end) of the switch S42. In the switched-capacitor circuit 20, the switch S33 is an example of an eighth switch.

The switch S34 is coupled between the other electrode (the fourth electrode) of the capacitor C15 (the second capacitor) and the node N2. Specifically, the one end (e.g., the first end) of the switch S34 is coupled to the other electrode (the fourth electrode) of the capacitor C15 and the one of the two electrodes of the capacitor C16. The other end (e.g., a second end) of the switch S34 is coupled to the node N2. That is, the other end (e.g., the second end) of the switch S34 is coupled to the other end (e.g., the second end) of the switch S21, the other end (e.g., the second end) of the switch S32, and the other end (e.g., the second end) of the switch S23. In the switched-capacitor circuit 20, the switch S34 is an example of a sixth switch.

The switch S43 is coupled between the other electrode of the capacitor C16 and the ground. Specifically, the one end (e.g., the first end) of the switch S43 is coupled to the other electrode of the capacitor C16. The other end (e.g., a second end) of the switch S43 is coupled to the ground.

The switch S44 is coupled between the other electrode of the capacitor C16 and the node N1. Specifically, the one end (e.g., the first end) of the switch S44 is coupled to the other electrode of the capacitor C16. The other end (e.g., a second end) of the switch S44 is coupled to the node N1. That is, the other end (e.g., the second end) of the switch S44 is coupled to the other end (e.g., the second end) of the switch S31, the other end (e.g., the second end) of the switch S42, and the other end (e.g., the second end) of the switch S33.

According to the exemplary aspect, a first set of switches, including the switches S12, S13, S22, S23, S32, S33, S42, and S43, and a second set of switches, including the switches S11, S14, S21, S24, S31, S34, S41, and S44, are complementarily switched on and off. Specifically, in the first phase, the first set of switches are turned on while the second set of switches are turned off during operation. In the second phase, the first set of switches are turned off while the second set of switches are turned on during operation.

For example, the capacitors C11 to C13 charge the capacitors C21 to C24 in one of the first and second phases, and the capacitors C14 to C16 charge the capacitors C21 to C24 in another of the first and second phases. That is, the capacitors C21 to C24 are always charged from the capacitors C11 to C13 or the capacitors C14 to C16. Accordingly, even when electric current flows from the nodes N1 to N4 to the supply modulator 30 at high speed, electric charges are supplied to the nodes N1 to N4 at high speed. This configuration reduces fluctuations in potentials at the nodes N1 to N4.

By operating as described above, the switched-capacitor circuit 20 is configured to maintain substantially equal voltage across each of the capacitors C21 to C24. Specifically, the four nodes N1 to N4 are respectively maintained at the voltages V1 to V4 (voltages relative to the ground potential) that satisfy V1:V2:V3:V4=1:2:3:4. The voltage levels of the voltages V1 to V4 correspond to the plural discrete voltage levels to be supplied to the supply modulator 30 by the switched-capacitor circuit 20.

The voltage ratio V1:V2:V3:V4 is not limited to 1:2:3:4. For example, the voltage ratio V1:V2:V3:V4 may be 1:2:4:8.

### 2.8. Supply Modulator

As illustrated in FIG. 4, the supply modulator 30 includes plural (four in the example in FIG. 4) input terminals 131 to 134, plural (four in the example in FIG. 4) switches S51 to S54, an output terminal 130, and a control terminal 135.

The output terminal 130 is coupled to the envelope amplifier 2. The output terminal 130 is a terminal to supply the voltage selected from the voltages V1 to V4 to the envelope amplifier 2 as the output voltage Vcc.

The plural input terminals 131 to 134 are coupled to the nodes N4 to N1 of the switched-capacitor circuit 20, respectively. The plural input terminals 131 to 134 are terminals receiving the voltages V4 to V1 from the switched-capacitor circuit 20.

The control terminal 135 is an input terminal for a control signal Sg3 from the digital control circuit 60. The control signal Sg3 is a signal to control on/off of the plural switches S51 to S54, which are included in the supply modulator 30. The supply modulator 30 controls on/off of the plural switches S51 to S54 based on the control signal Sg3.

The switch S51 is coupled between the input terminal 131 and the output terminal 130. Specifically, the switch S51 has a first terminal coupled to the input terminal 131 and a second terminal coupled to the output terminal 130. In the aforementioned connection configuration, the switch S51 is switched on and off to switch connection and non-connection between the input terminal 131 and the output terminal 130.

The switch S52 is coupled between the input terminal 132 and the output terminal 130. Specifically, the switch S52 has a first terminal coupled to the input terminal 132 and a second terminal coupled to the output terminal 130. In the aforementioned connection configuration, the switch S52 is switched on and off to switch connection and non-connection between the input terminal 132 and the output terminal 130. In the supply modulator 30, the switch S52 is an example of a 10th switch.

The switch S53 is coupled between the input terminal 133 and the output terminal 130. Specifically, the switch S53 has a first terminal coupled to the input terminal 133 and a second terminal coupled to the output terminal 130. In the aforementioned connection configuration, the switch S53 is switched on and off to switch connection and non-connection between the input terminal 133 and the output terminal 130. In the supply modulator 30, the switch S53 is an example of a ninth switch.

The switch S54 is coupled between the input terminal 134 and the output terminal 130. Specifically, the switch S54 has a first terminal coupled to the input terminal 134 and a second terminal coupled to the output terminal 130. In the aforementioned connection configuration, the switch S54 is switched on and off to switch connection and non-connection between the input terminal 134 and the output terminal 130.

The plural switches S51 to S54 are controlled so that each of the plural switches S51 to S54 be exclusively turned on. That is, only one of the switches S51 to S54 is turned on while the other switches are turned off. The supply modulator 30 is thereby configured to output one voltage selected from the voltages V1 to V4.

By having the aforementioned configuration, the supply modulator 30 receives the digital control signal corresponding to the envelope signal E1 through the control terminal 135 and controls on/off of the plural switches S51 to S54 based on the digital control signal received through the control terminal 135 to select at least one of the plural voltages V1 to V4 generated by the switched-capacitor circuit 20. The supply modulator 30 outputs the selected voltage.

In some cases, the voltage outputted from the supply modulator 30 does not have a rectangular waveform including only plural discrete voltages. Specifically, when the output voltage transits from a discrete voltage having a relatively low voltage level to a discrete voltage having a relatively high voltage level, overshoot voltage (e.g., spike-like voltage) occurs, and the waveform of the voltage outputted from the supply modulator 30 has a deformed rectangular shape. When the output voltage transits from a discrete voltage having a relatively high voltage level to a discrete voltage having a relatively low voltage level, undershoot voltage (e.g., a spike-like voltage) occurs, and the waveform of the voltage outputted from the supply modulator 30 has a deformed rectangular shape. The above-described deformation in the waveform of the output voltage from the supply modulator 30 causes noise. The amplitude of such a spike-like voltage increases as the absolute value of the rate of voltage change (dV/dt) increases.

### 2.9. Digital Control Circuit

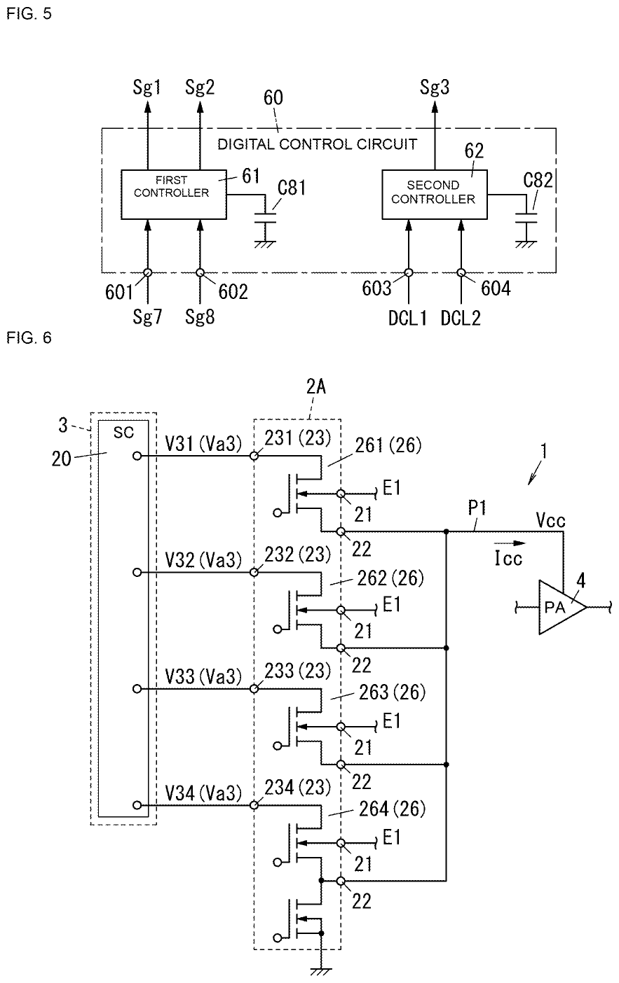

As illustrated in FIG. 5, the digital control circuit 60 includes a first controller 61, a second controller 62, two capacitors C81 and C82, and four control terminals 601 to 604. The four control terminals 601 to 604 of the digital control circuit 60 are coupled to the four second control terminals T5 (see FIG. 2), which are included in the radio-frequency system 200, one to one. The four control terminals 601 to 604 of the digital control circuit 60 are thereby coupled to the RF signal processing circuit 71 (see FIG. 2) of the communication device 9.

The first controller 61 receives a source-synchronous digital control signal from the RF signal processing circuit 71 through the control terminals 601 and 602 and processes the received digital control signal to generate the control signals Sg1 and Sg2.

The first controller 61 uses a set of a clock signal Sg7 and a data signal Sg8 as digital control signals for the pre-regulator circuit 10 and the switched-capacitor circuit 20. The clock signal Sg7 is inputted to the first controller 61 through the control terminal 601. The data signal Sg8 is inputted to the first controller 61 through the control terminal 602.

The second controller 62 is configured to process digitally controlled level signals DCL1 and DCL2, which are digital control signals received from the RF signal processing circuit 71 through the control terminals 603 and 604, to generate the control signal Sg3. The digitally controlled level signals DCL1 and DCL2 correspond to the envelope signal E1.

The digitally controlled level signals DCL1 and DCL2 are 1-bit signals. The voltages V1 to V4 are individually represented by a combination of two 1-bit signals. For example, V1, V2, V3, and V4 are represented by “00”, “01”, “10”, and “11”, respectively. The voltage levels may be expressed using a gray code. The supply modulator 30 is controlled by use of the two digitally controlled level signals in the aforementioned case. However, the number of digitally controlled level signals is not limited to two. For example, the number of digitally controlled level signals may be any number, such as one or three or more, depending on the number of voltage levels that are selectable by the supply modulator 30. The digital control signals used for controlling the supply modulator 30 are not limited to digitally controlled level signals.

The capacitor C81 is coupled between the first controller 61 and the ground. For example, the capacitor C81 is coupled between a power supply line that supplies electric power to the first controller 61 and the ground and serves as a bypass capacitor. The capacitor C82 is coupled between the second controller 62 and the ground. For example, the capacitor C82 is coupled between a power supply line that supplies electric power to the second controller 62 and the ground and serves as a bypass capacitor.

### 3. Operation of Analog ET circuit

Hereinafter, the operation (a voltage supply method) of the analog ET circuit 1 according to Embodiment 1 will be described with reference to FIG. 1.

First, the plural discrete voltages Va0 (the plural first discrete voltages Va1, the plural second discrete voltages Va2) are generated.

In the first voltage supply unit 3A of the voltage supply unit 3, the first switched-capacitor circuit 20A generates plural discrete voltages.

The first supply modulator 30A selects at least one of the plural discrete voltages generated by the first switched-capacitor circuit 20A and outputs the selected discrete voltage to the plus power supply terminal 24 of the envelope amplifier 2 as a first discrete voltage Va1.

In the second voltage supply unit 3B of the voltage supply unit 3, the second switched-capacitor circuit 20B generates plural discrete voltages.

The second supply modulator 30B is configured to select at least one of the plural discrete voltages generated by the second switched-capacitor circuit 20B and outputs the selected discrete voltage to the minus power supply terminal 25 of the envelope amplifier 2 as a second discrete voltage Va2.

Next, the envelope amplifier 2 receives the envelope signal E1 and the plural discrete voltages Va0 (the plural first discrete voltages Va1, the plural second discrete voltages Va2) and outputs the continuous output voltage Vcc.

Using the first discrete voltage Va1 supplied from the first voltage supply unit 3A through the plus power supply terminal 24 and the second discrete voltage Va2 supplied from the second voltage supply unit 3B through the minus power supply terminal 25, the envelope amplifier 2 outputs the output voltage Vcc corresponding to the envelope signal E1 to the power amplifier 4.

The first supply modulator 30A and the second supply modulator 30B switch the voltage level Ln of the first discrete voltage Va1 and the voltage level Ln-1 of the second discrete voltage Va2 so that the voltage level of the output voltage Vcc be higher than the voltage level Ln-1 of the second discrete voltage Va2 and be lower than the voltage level Ln of the first discrete voltage Va1.

The envelope amplifier 2 is supplied with the first discrete voltage Va1 having the voltage level Ln and the second discrete voltage Va2 having the voltage level Ln-1,which change over time depending on the envelope signal E1. That is, the envelope amplifier 2 is supplied with power supply voltage that changes over time and outputs the output voltage Vcc.

When output current Icc is flowing out of the envelope amplifier 2, the loss of the envelope amplifier 2 is [(First discrete voltage Va1−Output voltage Vcc)×Output current Icc]. When the output current Icc is flowing into the envelope amplifier 2, the loss of the envelope amplifier 2 is [(Output voltage Vcc−Second discrete voltage Va2)×Output current Icc].

In the power supply lines of the envelope amplifier 2, the voltages Va1 on the plus side and the voltages Va2 on the minus side can be both switched. The power supply voltage for the envelope amplifier 2 can thereby be varied, so that the loss of the envelope amplifier 2 can be reduced compared to the case where the power supply voltage of the envelope amplifier 2 is constant.

### 4. Effect

In the analog ET circuit 1 according to Embodiment 1, the voltage supply unit 3 is configured to supply the plural discrete voltages Va0 to the envelope amplifier 2. The discrete voltages Va0 to be supplied to the envelope amplifier 2 can be switched depending on the voltage of the envelope signal E1 to be received by the envelope amplifier 2. This configuration reduces the loss of the envelope amplifier 2.

In the analog ET circuit 1 according to Embodiment 1, the plural discrete voltages Va0 are selectively supplied to the envelope amplifier 2. The discrete voltages Va0 to be supplied to the envelope amplifier 2 can thereby be switched depending on the voltage of the envelope signal E1 to be received by the envelope amplifier 2. This configuration reduces the loss of the envelope amplifier 2.

In the analog ET circuit 1 according to Embodiment 1, no switching element is directly coupled to an element (the power amplifier 4, for example) on the output side of the analog ET circuit 1. This configuration reduces switching noise leakage to elements on the output side of the analog ET circuit 1.

In the analog ET circuit 1 according to Embodiment 1, the supply modulator 30 (the first supply modulator 30A, the second supply modulator 30B), which selectively outputs at least one of the plural discrete voltages Va0 to the envelope amplifier 2, is included in the voltage supply unit 3. The voltage supply unit 3 can thereby output an appropriate discrete voltage Va0 to the envelope amplifier 2.

The analog ET circuit 1 according to Embodiment 1 outputs the continuous output voltage Vcc depending on the first discrete voltage Va1 supplied to the plus power supply terminal 24 (the high side) of the envelope amplifier 2 and the second discrete voltage Va2 supplied to the minus power supply terminal 25 (the low side) of the envelope amplifier 2. The maximum applied voltage to the envelope amplifier 2 is therefore limited to the difference between the first discrete voltage Va1 and the second discrete voltage Va2. This configuration reduces the withstand voltage required for the envelope amplifier 2.

In the analog ET circuit 1 according to Embodiment 1, the voltage supply unit 3 includes the switched-capacitor circuit 20 (the first switched-capacitor circuit 20A, the second switched-capacitor circuit 20B). The plural discrete voltages Va0 (the first discrete voltages Va1, the second discrete voltages Va2) can thereby be generated efficiently.

In the radio-frequency system 200 according to Embodiment 1, the voltage supply unit 3 is configured to supply the plural discrete voltages Va0 to the envelope amplifier 2 in the analog ET circuit 1. The discrete voltages Va0 to be supplied to the envelope amplifier 2 can be switched depending on the voltage of the envelope signal E1 to be received by the envelope amplifier 2. This configuration reduces the loss of the envelope amplifier 2.

In the radio-frequency system 200 according to Embodiment 1, no switching element is directly coupled to an element (the power amplifier 4, for example) on the output side of the analog ET circuit 1 in the analog ET circuit 1. This configuration reduces switching noise leakage to elements on the output side of the analog ET circuit 1.

In the communication device 9 according to Embodiment 1, the voltage supply unit 3 is configured to supply the plural discrete voltages Va0 to the envelope amplifier 2 in the analog ET circuit 1 of the radio-frequency system 200. The discrete voltages Va0 to be supplied to the envelope amplifier 2 can thereby be switched depending on the voltage of the envelope signal E1 to be received by the envelope amplifier 2. This configuration reduces the loss of the envelope amplifier 2.

In the communication device 9 according to Embodiment 1, no switching element is directly coupled to an element (the power amplifier 4, for example) on the output side of the analog ET circuit 1 in the analog ET circuit 1 of the radio-frequency system 200. This configuration reduces switching noise leakage to elements on the output side of the analog ET circuit 1.

In the voltage supply method according to Embodiment 1, the plural discrete voltages Va0 are outputted in advance. It is therefore possible to switch the discrete voltages Va0 depending on the voltage of the envelope signal E1, thus reducing the loss.

In the voltage supply method according to Embodiment 1, no switching element is directly coupled to an element (a power amplifier, for example) on the output side. This configuration reduces switching noise leakage to elements on the output side.

### EXEMPLARY EMBODIMENT 2

An analog ET circuit 1 according to Embodiment 2 is different from the analog ET circuit 1 (see FIG. 1) according to Embodiment 1 in that the analog ET circuit 1 according to Embodiment 2 includes an envelope amplifier 2A as illustrated in FIG. 6. It is noted that in the analog ET circuit 1 according to Embodiment 2, the same constituent components as those of the analog ET circuit 1 according to Embodiment 1 are denoted by the same reference numerals, and the description thereof is omitted.

### 1. Configuration of Analog ET circuit

As illustrated in FIG. 6, the analog ET circuit 1 of Embodiment 2 includes an envelope amplifier 2A and a voltage supply unit 3.

### 1.1 Envelope Amplifier

As illustrated in FIG. 6, the envelope amplifier 2A of Embodiment 2 includes plural MOSFETs (amplification elements) 26. The plural MOSFETs 26 are configured so as to be supplied with plural discrete voltages Va3 from the voltage supply unit 3.

The plural MOSFETs 26 include a first MOSFET 261, a second MOSFET 262, a third MOSFET 263, and a fourth MOSFET 264. The first MOSFET 261 is configured to receive a direct-current voltage V31 having a voltage level LA. The second MOSFET 262 is configured to receive a direct-current voltage V32 having a voltage level L3, which is lower than the voltage level LA. The third MOSFET 263 is configured to receive a direct-current voltage V33 having a voltage level L2, which is lower than the voltage level L3. The fourth MOSFET 264 is configured to receive a direct-current voltage V34 having a voltage level L1, which is lower than the voltage level L2.

### 1.2 Voltage Supply Unit

As illustrated in FIG. 6, the voltage supply unit 3 of Embodiment 2 includes a switched-capacitor circuit 20. The switched-capacitor circuit 20 of Embodiment 2 has the same configuration and function as those of the switched-capacitor circuit 20 (see FIG. 4) of Embodiment 1.

### 2. Operation of Analog ET circuit

Next, the operation (the voltage supply method) of the analog ET circuit 1 according to Embodiment 2 will be described with reference to the drawing.

In the envelope amplifier 2A, the plural MOSFETs 26 are supplied with the plural discrete voltages Va3 from the voltage supply unit 3.

The plural MOSFETs 26 operate depending on the envelope signal E1. To be more specific, for example, when the voltage level of the output voltage Vcc is higher than the voltage level Ln-1 and lower than the voltage level Ln and the envelope amplifier 2A is delivering the output current Icc, the MOSFET 26 that receives the direct-current voltage Va3 having the voltage level Ln operates in the saturation region or the linear region while the other MOSFETs 26 are off. When the voltage level of the output voltage Vcc is higher than the voltage level Ln-1 and lower than the voltage level Ln and the envelope amplifier 2A is absorbing the output current Icc, the MOSFET 26 that receives the direct-current voltage Va3 having the voltage level Ln-1 operates in the saturation region or the linear region while the other MOSFETs 26 are off.

For example, when the voltage level of the output voltage Vcc is higher than the voltage level L3 and lower than the voltage level L4 and the envelope amplifier 2A is delivering the output current Icc, the first MOSFET 261, which receives the direct-current voltage V31 having the voltage level LA, operates in the saturation region or the linear region while the second, third, and fourth MOSFETs 262 to 264 are off. When the voltage level of the output voltage Vcc is higher than the voltage level L3 and lower than the voltage level LA and the envelope amplifier 2A is absorbing the output current Icc, the second MOSFET 262, which receives the direct-current voltage V32 having the voltage level L3, operates in the saturation region or the linear region while the first, third, and fourth MOSFETs 261, 263, and 264 are off.

In operation, the envelope amplifier 2A individually switches on and off the plural MOSFETs 26 so as to output the output voltage Vcc depending on the envelope signal E1.

When the output current Icc is flowing out of the envelope amplifier 2A, the loss of the envelope amplifier 2A is [(First discrete voltage Va3−Output voltage Vcc)×Output current Icc]. When the output current Icc being drawn into the envelope amplifier 2A, the loss of the envelope amplifier 2A is [(Output voltage Vcc−Second discrete voltage Va3)×Output current Icc].

Since the power supply line of the envelope amplifier 2A can be switched, the loss of the envelope amplifier 2A can be reduced compared to the case where the power supply voltage for the envelope is constant.

### 3. Effect

In the analog ET circuit 1 according to Embodiment 2, the plural discrete voltages Va3 are directly supplied to the envelope amplifier 2A from the voltage supply unit 3. The analog ET circuit 1 can therefore be reduced in size compared to the case where discrete voltages are supplied to an envelope amplifier from a voltage supply unit through a switch.

### EXEMPLARY EMBODIMENT 3

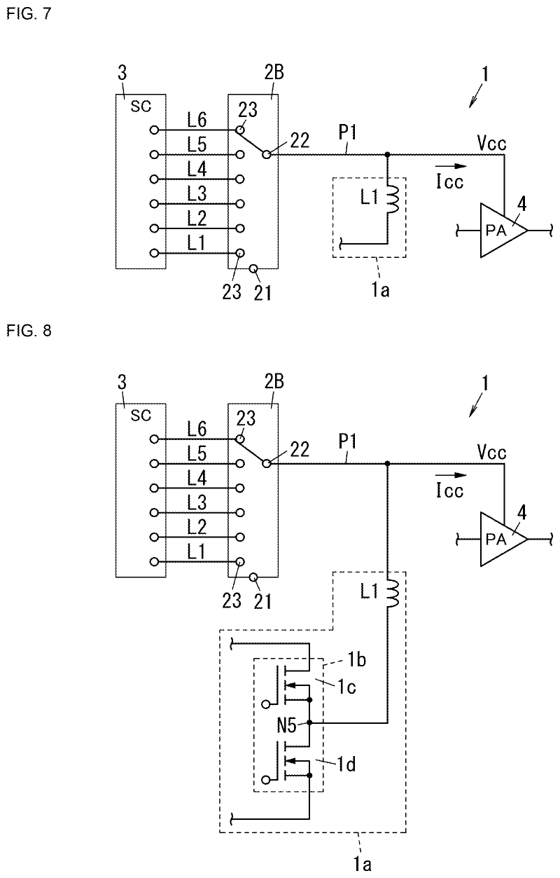

An analog ET circuit 1 according to Embodiment 3 is different from the analog ET circuit 1 (see FIG. 6) according to Embodiment 2 in that the analog ET circuit 1 according to Embodiment 3 includes a direct-current power source 1a as illustrated in FIG. 7. In the analog ET circuit 1 according to Embodiment 3, the same constituent components as those of the analog ET circuit 1 according to Embodiment 2 are denoted by the same reference numerals, and the description thereof is omitted.

### 1. Configuration of Analog ET circuit

As illustrated in FIG. 7, the analog ET circuit 1 of Embodiment 3 includes an envelope amplifier 2B, a voltage supply unit 3, and the direct-current power source 1a.

### 1.1 Envelope Amplifier

As illustrated in FIG. 7, the envelope amplifier 2B of Embodiment 3 is coupled to the voltage supply unit 3. The envelope amplifier 2B has the same configuration and function as those of the envelope amplifier 2B (see FIG. 6) of Embodiment 2, for example.

### 1.2 Voltage Supply Unit

The voltage supply unit 3 of Embodiment 3 includes a switched-capacitor circuit 20 as illustrated in FIG. 7, similarly to the voltage supply unit 3 (see FIG. 6) of Embodiment 2. The switched-capacitor circuit 20 of Embodiment 3 has the same configuration and function as those of the switched-capacitor circuit 20 (see FIG. 4) of Embodiment 1.

### 1.3 Direct-current Power Source

The direct-current power source 1a of Embodiment 3 is configured to supply direct current to a path P1 between the envelope amplifier 2B and a power amplifier 4 as illustrated in FIG. 7.

The direct-current power source 1a of Embodiment 3 includes an inductor L1.

The inductor L0 is coupled to the path P1 between the envelope amplifier 2B and the power amplifier 4. To be more specific, a first end of the inductor L0 is coupled to a power source (not illustrated), and a second end of the inductor L0 is coupled to the path P1 between the envelope amplifier 2B and the power amplifier 4.

The direct-current power source 1a supplies direct current through the inductor L0.

### 2. Operation of Analog ET circuit

Next, the operation (the voltage supply method) of the analog ET circuit 1 according to Embodiment 3 will be described with reference to the drawing.

The envelope amplifier 2B outputs a signal corresponding to the envelope signal E1. The direct-current power source 1a supplies direct current. The direct current from the direct-current power source 1a is outputted to the power amplifier 4 together with the output current from the envelope amplifier 2B.

### 3. Effect

The analog ET circuit 1 according to Embodiment 3 includes the direct-current power source 1a configured to supply direct current to the path P1 between the envelope amplifier 2B and the power amplifier 4. The envelope amplifier 2B can therefore be reduced in size.

### EXEMPLARY EMBODIMENT 4

The analog ET circuit 1 according to Embodiment 4 is different from the analog ET circuit 1 (see FIG. 7) according to Embodiment 3 in that the analog ET circuit 1 according to Embodiment 4 includes a direct-current power source 1a as illustrated in FIG. 8. In the analog ET circuit 1 according to Embodiment 4, the same constituent components as those of the analog ET circuit 1 according to Embodiment 3 are denoted by the same reference numerals, and the description thereof is omitted.

### 1. Configuration of Analog ET circuit

The analog ET circuit 1 of Embodiment 4 includes the direct-current power source 1a illustrated in FIG. 8 instead of the direct-current power source 1a (see FIG. 7) of Embodiment 3. In the direct-current power source 1a of Embodiment 4, the description of the same configuration and function as those of the direct-current power source 1a of Embodiment 3 is omitted.

As illustrated in FIG. 8, the direct-current power source 1a of Embodiment 4includes an inductor L0 and a step-down converter 1b. The step-down converter 1b is configured to switch between plural voltage levels. The step-down converter 1b includes a first MOSFET 1c and a second MOSFET 1d. The first MOSFET 1c and the second MOSFET 1d are connected in series. The inductor L0 is coupled to a node N5 between the first MOSFET 1c and the second MOSFET 1d.

### 2. Effect

In the analog ET circuit 1 according to Embodiment 4, the step-down converter 1b configured to switch between plural voltage levels is provided for the direct-current power source 1a. This facilitates setting of a required magnitude of direct current.

### EXEMPLARY EMBODIMENT 5

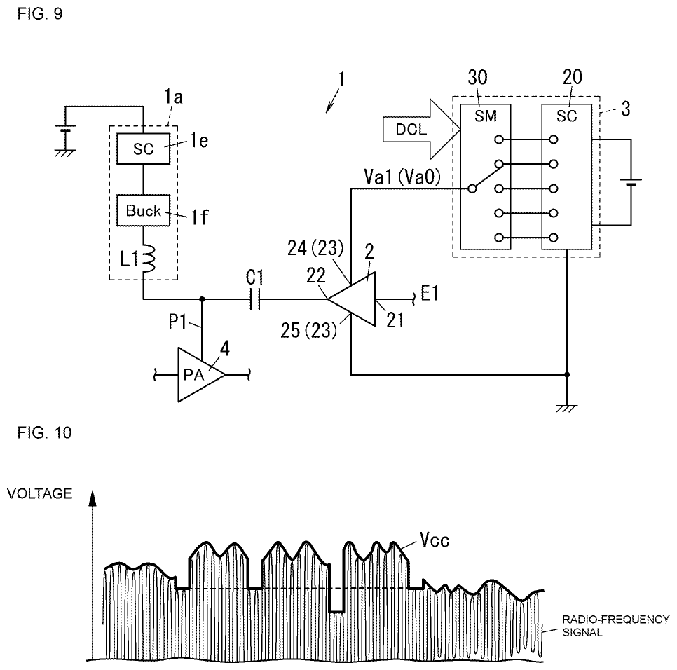

An analog ET circuit 1 according to Embodiment 5 is different from the analog ET circuit 1 (see FIG. 1) according to Embodiment 1 in that the analog ET circuit 1 according to Embodiment 5 includes a configuration as illustrated in FIG. 9. In the analog ET circuit 1 according to Embodiment 5, the same constituent components as those of the analog ET circuit 1 according to Embodiment 1 are denoted by the same reference numerals, and the description thereof is omitted.

### 1. Configuration of Analog ET Circuit

As indicated in FIG. 9, the analog ET circuit 1 according to Embodiment 5 includes an envelope amplifier 2, a voltage supply unit 3, a direct-current power source 1a, and a capacitor C1.

### 1.1 Envelope Amplifier

As illustrated in FIG. 9, the envelope amplifier 2 of Embodiment 5 is configured to receive an envelope signal E1 and plural discrete voltages Va0 and output a continuous output voltage Vcc. The envelope amplifier 2 is a linear amplifier, for example.

The envelope amplifier 2 includes an input terminal 21, an output terminal 22, and plural (two in the example in FIG. 9) power supply terminals 23. The input terminal 21 is a terminal receiving the envelope signal E1. The output terminal 22 is a terminal outputting the continuous output voltage Vcc. The plural power supply terminals 23 are terminals supplied with power supply voltage to operate the envelope amplifier 2. The plural power supply terminals 23 include a plus power supply terminal (the first power supply terminal) 24 and a minus power supply terminal (the second power supply terminal) 25. The plus power supply terminal 24 is a terminal supplied with plural first discrete voltages Va1. The minus power supply terminal 25 is a terminal having a ground potential.

### 1.2 Voltage Supply Unit

As illustrated in FIG. 9, the voltage supply unit 3 of Embodiment 5 includes a switched-capacitor circuit 20 and a supply modulator 30. The switched-capacitor circuit 20 of Embodiment 5 has the same configuration and function as those of the switched-capacitor circuit 20 (see FIG. 4) of Embodiment 1. The supply modulator 30 of Embodiment 5 has the same configuration and function as the supply modulator 30 (see FIG. 4) of Embodiment 1.

### 1.3 Direct-current Power Source

The direct-current power source 1a of Embodiment 5 includes a switched-capacitor circuit 1e, a buck converter 1f, and an inductor L0 as illustrated in FIG. 9. The switched-capacitor circuit 1e is configured to generate plural discrete voltages. The inductor L0 is coupled between the buck converter 1f and the path P1.

### 2. Operation of Analog ET circuit

Next, the operation (e.g., the voltage supply method) of the analog ET circuit 1 according to Embodiment 5 will be described with reference to the drawing.

According to the exemplary aspect, when the radio-frequency signal has a higher frequency, envelope tracking is repeated and the envelope signal E1 as generated is inputted to the envelope amplifier 2.

Normally, the voltage level of the power supply voltage to the envelope amplifier 2 is switched depending on the envelope signal E1.

On the other hand, when the voltage level of the envelope signal E1 is greatly different from the voltage level of the radio-frequency signal, the voltage supply unit 3 reduces voltage to a certain level and supplies the reduced voltage to the envelope amplifier 2.

In a low frequency band, the operation of analog ET is performed to improve the overall efficiency. In a higher frequency band, the operation of envelope tracking is repeated while the voltage is reduced in part causing a large loss to reduce the loss.

### 3. Effect

In the analog ET circuit 1 according to Embodiment 5, the direct-current power source 1a includes the switched-capacitor circuit 1e and the buck converter 1f. It is therefore possible to efficiently output direct current to the path P1 between the envelope amplifier 2 and the power amplifier 4.

### EXEMPLARY EMBODIMENT 6

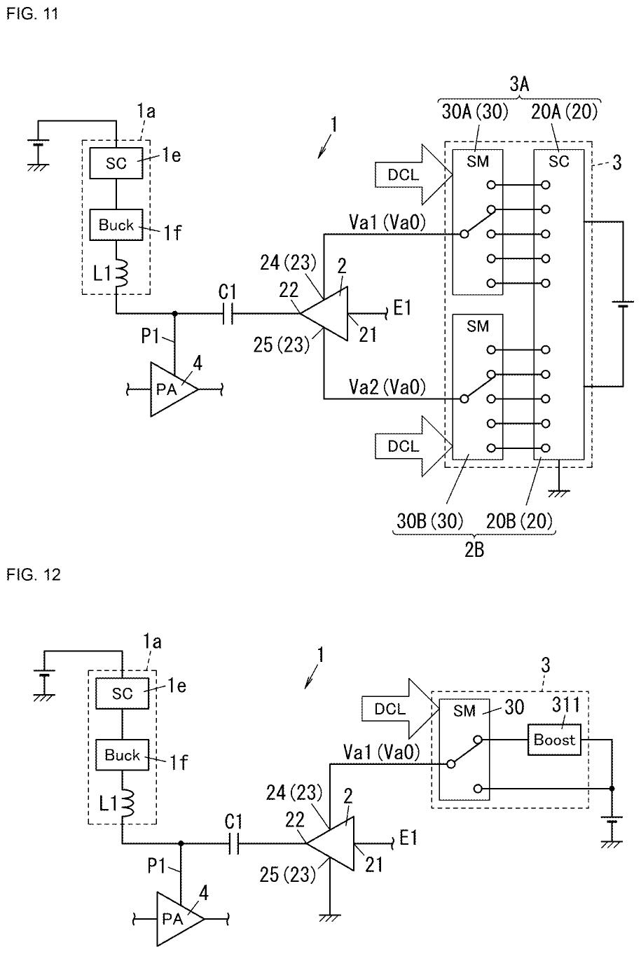

An analog ET circuit 1 according to Embodiment 6 is different from the analog ET circuit 1 (see FIG. 9) according to Embodiment 5 in that the analog ET circuit 1 according to Embodiment 6 includes a configuration as illustrated in FIG. 11. In the analog ET circuit 1 according to Embodiment 6, the same constituent components as those of the analog ET circuit 1 according to Embodiment 5 are denoted by the same reference numerals, and the description thereof is omitted.

### 1. Configuration

As illustrated in FIG. 11, the analog ET circuit 1 according to Embodiment 6 includes an envelope amplifier 2, a voltage supply unit 3, a direct-current power source 1a, and a capacitor C1.

As illustrated in FIG. 11, the voltage supply unit 3 of Embodiment 6 includes a switched-capacitor circuit 20, a first supply modulator 30A, and a second supply modulator 30B.

The switched-capacitor circuit 20 of Embodiment 6 is a circuit integrating the switched-capacitor circuit 20 of the first voltage supply unit 3A of Embodiment 1 and the switched-capacitor circuit 20 of the second voltage supply unit 3B of Embodiment 1.

The first supply modulator 30A of Embodiment 6 has the same configuration and function as those of the supply modulator 30 (see FIG. 4) of Embodiment 1. The second supply modulator 30B of Embodiment 6 has the same configuration and function as those of the supply modulator 30 of Embodiment 1.

### 2. Effect

In the analog ET circuit 1 according to Embodiment 6, the direct-current power source 1a includes the switched-capacitor circuit 1e and the buck converter If similarly to the analog ET circuit 1 according to Embodiment 5. It is therefore possible to efficiently output direct current to a path P1 between the envelope amplifier 2 and a power amplifier 4.

### EXEMPLARY EMBODIMENT 7

An analog ET circuit 1 according to Embodiment 7 is different from the analog ET circuit 1 (see FIG. 9) according to Embodiment 5 in that the analog ET circuit 1 according to Embodiment 7 includes a configuration as illustrated in FIG. 12. In the analog ET circuit 1 according to Embodiment 7, the same constituent components as those of the analog ET circuit 1 according to Embodiment 5 are denoted by the same reference numerals, and the description thereof is omitted.

### 1. Configuration of Analog ET circuit

As illustrated in FIG. 12, the analog ET circuit 1 according to Embodiment 7 includes an envelope amplifier 2, a voltage supply unit 3, a direct-current power source 1a, and a capacitor C1.

### 1.1 Envelope Amplifier

As illustrated in FIG. 12, the envelope amplifier 2 of Embodiment 7 is configured to receive an envelope signal E1 and plural discrete voltages Va0 and output a continuous output voltage Vcc. The envelope amplifier 2 is a linear amplifier, for example.

In Embodiment 7, the envelope amplifier 2 is configured to receive the envelope signal E1 and first discrete voltages Va1 and output the continuous output voltage Vcc.

The envelope amplifier 2 includes an input terminal 21, an output terminal 22, and plural (two in the example in FIG. 12) power supply terminals 23. The input terminal 21 is a terminal receiving the envelope signal E1. The output terminal 22 is a terminal outputting the continuous output voltage Vcc. The plural power supply terminals 23 are terminals supplied with power supply voltage to operate the envelope amplifier 2. The plural power supply terminals 23 include a plus power supply terminal (the first power supply terminal) 24 and a minus power supply terminal (the second power supply terminal) 25. The plus power supply terminal 24 is a terminal supplied with the plural discrete voltages Va1. The minus power supply terminal 25 is a terminal having a ground potential.

### 1.2 Voltage Supply Unit

As illustrated in FIG. 12, the voltage supply unit 3 of Embodiment 7 includes a booster (a DC-DC converter) 311 and a supply modulator 30.

### 2. Effect

In the analog ET circuit 1 according to Embodiment 7, the voltage supply unit 3 includes the DC-DC converter. The voltage supply unit 3 can therefore efficiently output the discrete voltages Va0 to the envelope amplifier 2.

### EXEMPLARY EMBODIMENT 8

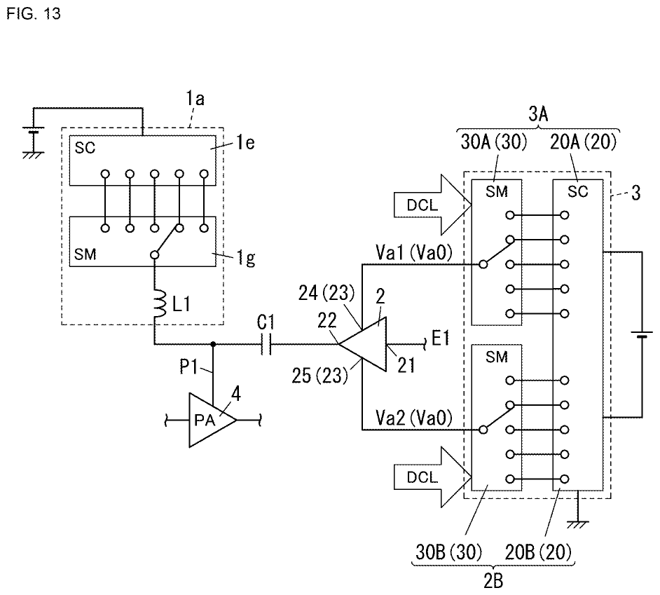

An analog ET circuit 1 according to Embodiment 8 is different from the analog ET circuit 1 (see FIG. 9) according to Embodiment 5 in that the analog ET circuit 1 according to Embodiment 8 includes a configuration as illustrated in FIG. 13. It is noted that in the analog ET circuit 1 according to Embodiment 8, the same constituent components as those of the analog ET circuit 1 according to Embodiment 5 are denoted by the same reference numerals, and the description thereof is omitted.

### 1. Configuration of Analog ET circuit

As illustrated in FIG. 13, the analog ET circuit 1 according to Embodiment 8 includes an envelope amplifier 2, a voltage supply unit 3, a direct-current power source 1a, and a capacitor C1.

### 1.1 Envelope Amplifier

As illustrated in FIG. 13, the envelope amplifier 2 of Embodiment 8 is configured to receive an envelope signal E1 and plural discrete voltages Va0 and output a continuous output voltage Vcc. The envelope amplifier 2 is a linear amplifier, for example.

In Embodiment 8, the envelope amplifier 2 is configured to receive the envelope signal E1, plural first discrete voltages Va1, and plural discrete voltages Va2 and output the continuous output voltage Vcc.

The envelope amplifier 2 includes an input terminal 21, an output terminal 22, and plural (two in the example in FIG. 13) power supply terminals 23. The input terminal 21 is a terminal receiving the envelope signal E1. The output terminal 22 is a terminal outputting the continuous output voltage Vcc. The plural power supply terminals 23 are terminals supplied with the plural discrete voltages Va0. In other words, the plural power supply terminals 23 are terminals supplied with power source voltage to operate the envelope amplifier 2.

The plural power supply terminals 23 include a plus power supply terminal (the first power supply terminal) 24 and a minus power supply terminal (the second power supply terminal) 25. The plus power supply terminal 24 is a terminal supplied with the plural first discrete voltages Va1. That is, the plus power supply terminal 24 is a terminal supplied with the voltages Va1 having high-voltage levels. The minus power supply terminal 25 is a terminal supplied with the plural second discrete voltages Va2. That is, the minus power supply terminal 25 is supplied with the voltages Va2 having low voltage levels. That is, the voltages Va2 supplied to the minus power supply terminal 25 are lower than the voltages Va1 supplied to the plus power supply terminal 24.

### 1.2 Voltage Supply Unit

As illustrated in FIG. 13, the voltage supply unit 3 of Embodiment 8 includes a switched-capacitor circuit 20, a first supply modulator 30A, and a second supply modulator 30B.

### 1.3 Direct-Current Power Source

As illustrated in FIG. 13, the direct-current power source 1a of Embodiment 8includes a switched-capacitor circuit 1e, a supply modulator 1g, and an inductor L0. The switched-capacitor circuit 1e is configured to generate plural discrete voltages. The supply modulator 1g is configured to selectively output the plural discrete voltages. The inductor L0 is coupled between the supply modulator 1g and a path P1.

### 2. Effect

In the analog ET circuit 1 according to Embodiment 8, the direct-current power source 1a includes the switched-capacitor circuit 1e and the supply modulator 1g. It is therefore possible to efficiently output direct current to the path P1 between the envelope amplifier 2 and the power amplifier 4.

### EXEMPLARY EMBODIMENT 9

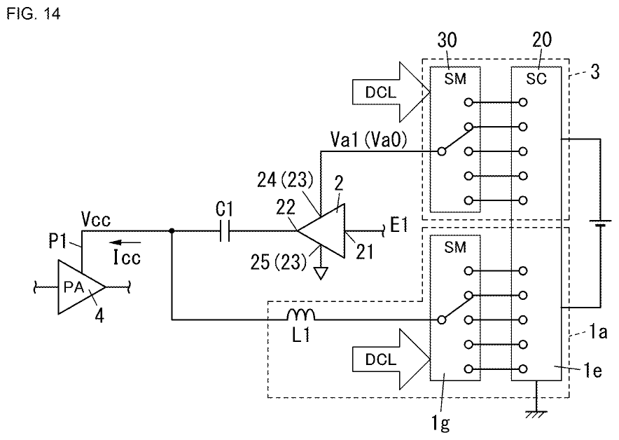

An analog ET circuit 1 according to Embodiment 9 is different from the analog ET circuit 1 (see FIG. 9) according to Embodiment 5 in that the analog ET circuit 1 according to Embodiment 9 includes a configuration as illustrated in FIG. 14. In the analog ET circuit 1 according to Embodiment 9, the same constituent components as those of the analog ET circuit 1 according to Embodiment 5 are denoted by the same reference numerals, and the description thereof is omitted.

### 1. Configuration

As illustrated in FIG. 14, the analog ET circuit 1 according to Embodiment 9 includes an envelope amplifier 2, a voltage supply unit 3, a direct-current power source 1a, and a capacitor C1.

### 1.1 Voltage Supply Unit

The voltage supply unit 3 of Embodiment 9 includes a switched-capacitor circuit 20 and a supply modulator 30 as illustrated in FIG. 14.

The switched-capacitor circuit 20 is configured to generate plural discrete voltages.

The supply modulator 30 is configured to selectively output one of the plural discrete voltages to the envelope amplifier 2.

### 1.2 Direct-current Power Source

As illustrated in FIG. 14, the direct-current power source 1a of Embodiment 9 is configured to supply direct current to a path P1 between the envelope amplifier 2 and the power amplifier 4.

The direct-current power source 1a of Embodiment 9 includes a switched-capacitor circuit 1e and a supply modulator 1g. The switched-capacitor circuit 1e is configured to generate plural discrete voltages. The supply modulator 1g is configured to selectively output one of the plural discrete voltages. The supply modulator 1g has a function of adjusting the duty ratio of a first discrete voltage and a second discrete voltage among the plural discrete voltages.

In the analog ET circuit 1 according to Embodiment 9, the switched-capacitor circuit 20 of the voltage supply unit 3 is integrated with the switched-capacitor circuit 1e of the direct-current power source 1a.

### 2. Effect

In the analog ET circuit 1 according to Embodiment 9, the direct-current power source 1a includes the switched-capacitor circuit 1e and the supply modulator 1g, and the supply modulator 1g of the direct-current power source 1a has a function of adjusting the duty ratio of the first discrete voltage and the second discrete voltage among the plural discrete voltages. The direct-current power source is therefore configured to output appropriate direct current.

The analog ET circuit 1 according to Embodiment 9 includes the direct-current power source 1a, and the voltage supply unit 3 includes the switched-capacitor circuit 20 and the supply modulator 30. It is therefore possible to output appropriate discrete voltages Va0 to the envelope amplifier 2.

### 3. Modification of Exemplary Embodiment 9

As a modification of Embodiment 9, the voltage outputted from the supply modulator 1g may be continuously varied by smoothly changing the gate voltage of the supply modulator 1g of the direct-current power source 1a.

### ADDITIONAL REFINEMENTS OF THE EXEMPLARY EMBODIMENTS 1 TO 9

In Embodiments 1 to 9, the method of controlling the envelope amplifier 2 includes receiving the envelope signal E1 to control the envelope amplifier 2.

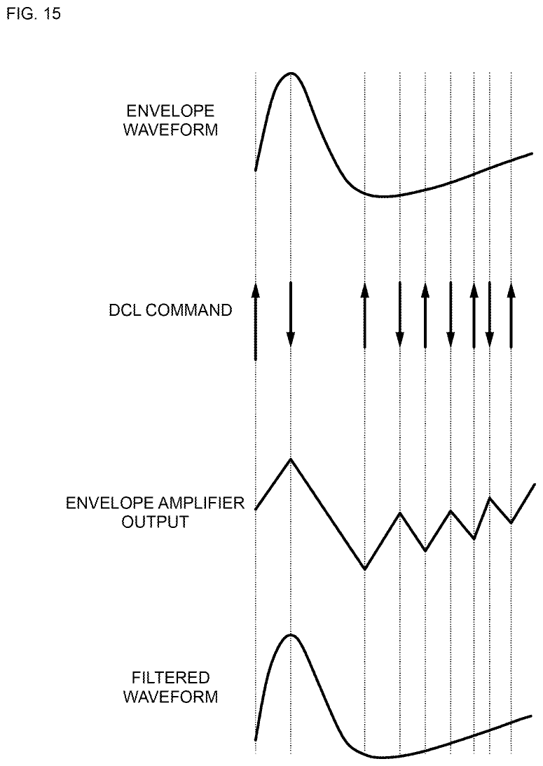

As another method of controlling the envelope amplifier 2, in modifications or refinements of Embodiments 1 to 9, the envelope amplifier 2 may be controlled by using a digital 2-bit signal (a digital control line, DCL). In this case, using edge trigger (asynchronous communication) DCL commands for the envelope waveform illustrated in FIG. 15 can ensure high communication speed. A signal with a hamming distance of 1 has only two values and can control only “the timing of voltage changes” and “the direction of voltage changes”.

For example, envelope tracking can be conducted with DCL alone if the voltage is designed to transit at a previously determined voltage change rate. The output voltage Vcc outputted from the envelope amplifier 2 has a waveform as illustrated in FIG. 15. The voltage change rate may be variable. For example, the voltage change rate is set low when the envelope frequency is low (the number of RBs is small) or the PAPR is small.

To control the envelope amplifier 2 using DCL, a filter can be provided on the output side (the subsequent stage) of the envelope amplifier 2. When a filter is provided on the output side of the envelope amplifier 2, the output voltage Vcc outputted from the filter has a waveform as illustrated in FIG. 15.

In such a case, the output voltage does not have a lot of radio-frequency (RF) components unlike the control using switching. It is therefore possible to prevent deterioration of out-of-band emissions and reduce the size of the filter.

It is noted that the above-described embodiments and modifications are only part of the various embodiments and modifications. Furthermore, the exemplary embodiments and modifications can be variously changed depending on the designs and the like as long as the object of the present invention is achieved as would be appreciated to one skilled in the art.

### EXEMPLARY ASPECTS

The specification discloses the following aspects.

An analog ET circuit (1) according to a first exemplary aspect includes an envelope amplifier (2) and a voltage supply unit (3). The voltage supply unit (3) is configured to supply plural discrete voltages (Va0) to the envelope amplifier (2). The envelope amplifier (2) is configured to receive an envelope signal (E1) and the plural discrete voltages (Va0) and output a continuous output voltage (Vcc).

According to the analog ET circuit (1) of the first exemplary aspect, the discrete voltages (Va0) to be supplied to the envelope amplifier (2) can be switched depending on the voltage of the envelope signal (E1) to be received by the envelope amplifier (2). This configuration reduces the loss of the envelope amplifier (2).

According to the analog ET circuit (1) of the first exemplary aspect, no switching element is directly coupled to an element (the power amplifier 4, for example) on the output side of the analog ET circuit (1). This configuration reduces switching noise leakage to elements on the output side of the analog ET circuit (1).

An analog ET circuit (1) according to a second exemplary aspect includes an envelope amplifier (2) and a voltage supply unit (3). The voltage supply unit (3) is configured to supply plural discrete voltages (Va0) to the envelope amplifier (2). The envelope amplifier (2) includes an input terminal (21), an output terminal (22), and a power supply terminal (23). The input terminal (21) is a terminal receiving an envelope signal (E1). The output terminal (22) is a terminal outputting a continuous output voltage (Vcc). The power supply terminal (23) is a terminal supplied with the plural discrete voltages (Va0).

According to the analog ET circuit (1) of the second exemplary aspect, the discrete voltages (Va0) to be supplied to the envelope amplifier (2) can be switched depending on the voltage of the envelope signal (E1) to be received by the envelope amplifier (2). This configuration reduces the loss of the envelope amplifier (2).

In the analog ET circuit (1) of the second exemplary aspect, no switching element is directly coupled to an element (the power amplifier 4, for example) on the output side of the analog ET circuit (1). This configuration reduces switching noise leakage to elements on the output side of the analog ET circuit (1).

According to an analog ET circuit (1) of a third exemplary aspect, the voltage supply unit (3) includes a supply modulator (30) in the first or second aspect. The supply modulator (30) is configured to selectively output one of the plural discrete voltages (Va0) to the envelope amplifier (2).

According to the analog ET circuit (1) of the third aspect, an appropriate discrete voltage (Va0) can be output to the envelope amplifier (2).

According to an analog ET circuit (1) of a fourth exemplary aspect, the voltage supply unit (3) includes a first voltage supply unit (3A) and a second voltage supply unit (3B) in the first aspect. The first voltage supply unit (3A) is configured to supply plural first discrete voltages (Va1) to a high side of the envelope amplifier (2). The second voltage supply unit (3B) is configured to supply plural second discrete voltages (Va2) to a low side of the envelope amplifier (2). The envelope amplifier (2) is configured to receive the envelope signal (E1), the plural first discrete voltages (Va1), and the plural second discrete voltages (Va2) and output the continuous output voltage (Vcc).

According to the analog ET circuit (1) of the fourth aspect, the maximum applied voltage to the envelope amplifier (2) is limited to the difference between the first discrete voltages (Va1) and the second discrete voltages (Va2). This configuration reduces the withstand voltage required for the envelope amplifier (2).

According to an analog ET circuit (1) of a fifth exemplary aspect, the voltage supply unit (3) includes a first voltage supply unit (3A) and a second voltage supply unit (3B) in the second aspect. The first voltage supply unit (3A) is configured to supply plural first discrete voltages (Va1) to a high side of the envelope amplifier (2). The second voltage supply unit (3B) is configured to supply plural second discrete voltages (Va2) to a low side of the envelope amplifier (2). The power supply terminal (23) includes a first power supply terminal (24) and a second power supply terminal (25). The first power supply terminal (24) is a terminal supplied with the plural first discrete voltages (Va1). The second power supply terminal (25) is a terminal supplied with the plural second discrete voltages (Va2).

According to the analog ET circuit (1) of the fifth exemplary aspect, the maximum applied voltage to the envelope amplifier (2) is limited to the difference between the first discrete voltages (Va1) and the second discrete voltages (Va2). This configuration reduces the withstand voltage required for the envelope amplifier (2).

According to an analog ET circuit (1) of a sixth exemplary aspect, the envelope amplifier (2) includes plural amplification elements (MOSFETs 26) in any one of the first to fifth aspects. The plural amplification elements are configured to be supplied with the plural discrete voltages from the voltage supply unit (3).

According to the analog ET circuit (1) of the sixth exemplary aspect, the analog ET circuit (1) can be reduced in size compared to the case where the envelope amplifier (2) is supplied with discrete voltages from the voltage supply unit (3) through a switch.

An analog ET circuit (1) according to a seventh exemplary aspect further includes a direct-current power source (1a) in any one of the first to sixth aspects. The direct-current power source (1a) is configured to supply direct current to a path (P1) between the envelope amplifier (2) and a power amplifier (4).

According to the analog ET circuit (1) of the seventh aspect, the envelope amplifier (2) can be reduced in size.

According to an analog ET circuit (1) of an eighth exemplary aspect, the direct-current power source (1a) includes a step-down converter (1b) in the seventh aspect. The step-down converter (1b) is configured to switch between plural voltage levels.

According to the analog ET circuit (1) of the eighth aspect, it is possible to easily set a necessary magnitude of direct current.

According to an analog ET circuit (1) of a ninth exemplary aspect, the direct-current power source (1a) includes a switched-capacitor circuit (1e), a buck converter (1f), and an inductor (L0) in the seventh aspect. The switched-capacitor circuit (1e) is configured to generate the plural discrete voltages (Va0). The inductor (L0) is coupled between the buck converter (1f) and the path (P1).

According to the analog ET circuit (1) of the ninth aspect, direct current can be efficiently outputted to the path (P1) between the envelope amplifier (2) and the power amplifier (4).

According to an analog ET circuit (1) of a tenth exemplary aspect, the direct-current power source (1a) includes a switched-capacitor circuit (1e), a supply modulator (1g), and an inductor (L0) in the seventh aspect. The switched-capacitor circuit (1e) is configured to generate the plural discrete voltages. The supply modulator (1g) is configured to selectively output the plural discrete voltages. The inductor (L0) is coupled between the supply modulator (1g) and the path (P1).

According to the analog ET circuit (1) of the tenth aspect, direct current can be efficiently outputted to the path (P1) between the envelope amplifier (2) and the power amplifier (4).

According to an analog ET circuit (1) of an eleventh exemplary aspect, the voltage supply unit (3) includes the switched-capacitor circuit (20) in any one of the first to 10th aspects. The switched-capacitor circuit (20) is configured to generate plural discrete voltages depending on input voltage.

According to the analog ET circuit (1) of the eleventh aspect, the plural discrete voltages (Va0) can be efficiently generated.

According to an analog ET circuit (1) of a twelfth exemplary aspect, the voltage supply unit (3) includes a DC-DC converter (the booster 311) in any one of the first to 10^{th} aspect.

According to the analog ET circuit (1) of the twelfth aspect, the discrete voltages (Va0) can be efficiently outputted to the envelope amplifier (2).

An analog ET circuit (1) according to a thirteenth exemplary aspect further includes a direct-current power source (1a) in any one of the first to 12^{th} aspects. The direct-current power source (1a) is configured to supply direct current to a path (P1) between the envelope amplifier (2) and a power amplifier (4). The direct-current power source (1a) includes a switched-capacitor circuit (1e) and a supply modulator (1g). The switched-capacitor circuit (1e) is configured to generate plural discrete voltages. The supply modulator (1g) is configured to selectively output one of the plural discrete voltages. The supply modulator (1g) of the direct-current power source (1a) has a function of adjusting the duty ratio of a first discrete voltage and a second discrete voltage among the plural discrete voltages (Va0).

According to the analog ET circuit (1) of the thirteenth aspect, the direct-current power source (1a) can output appropriate direct current.

An analog ET circuit (1) according to a fourteenth exemplary aspect further includes a direct-current power source (1a) in any one of the first to 12th aspects. The direct-current power source (1a) is configured to supply direct current to a path (P1) between the envelope amplifier (2) and the power amplifier (4). The voltage supply unit (3) includes a switched-capacitor circuit (20) and a supply modulator 30. The switched-capacitor circuit (20) is configured to generate plural discrete voltages. The supply modulator (30) is configured to selectively output one of the plural discrete voltages to the envelope amplifier (2). The direct-current power source (1a) includes a switched-capacitor circuit (1e) and the supply modulator (1g). The switched-capacitor circuit (20) of the voltage supply unit (3) is integrated with the switched-capacitor circuit (1e) of the direct-current power source (1a).

According to the analog ET circuit (1) of the fourteenth aspect, an appropriate discrete voltage (Va0) can be output to the envelope amplifier (2).

A radio-frequency system (200) according to a fifteenth exemplary aspect includes the analog ET circuit (1) according to any one of the first to 14th aspects and a power amplifier (4). The power amplifier (4) is coupled to the analog ET circuit (1).

According to the radio-frequency system (200) of the fifteenth aspect, in the analog ET circuit (1), the discrete voltages (Va0) to be supplied to the envelope amplifier (2) can be switched depending on the voltage of the envelope signal (E1) to be received by the envelope amplifier (2). This configuration reduces the loss of the envelope amplifier (2).

According to the radio-frequency system (200) of the fifteenth aspect, in the analog ET circuit (1), no switching element is directly coupled to an element (the power amplifier 4, for example) on the output side of the analog ET circuit (1). This configuration reduces switching noise leakage to elements on the output side of the analog ET circuit (1).

A communication device (9) according to a sixteenth exemplary aspect includes a radio-frequency system (200) according to the 15th aspect and a signal processing circuit (7). The signal processing circuit (7) is coupled to the radio-frequency system (200).

According to the communication device (9) of the sixteenth aspect, in the analog ET circuit (1) of the radio-frequency system (200), the discrete voltages (Va0) to be supplied to the envelope amplifier (2) can be switched depending on the voltage of the envelope signal (E1) to be received by the envelope amplifier (2). This configuration reduces the loss of the envelope amplifier (2).

According to the communication device (9) of the sixteenth aspect, in the analog ET circuit (1) of the radio-frequency system (200), no switching element is directly coupled to an element (the power amplifier 4, for example) on the output side of the analog ET circuit (1). This configuration reduces switching noise leakage to elements on the output side of the analog ET circuit (1).

A voltage supply method according to a seventeenth exemplary aspect generates plural discrete voltages (Va0) in advance; and receives an envelope signal (E1) and the plural discrete voltages (Va0) to output a continuous output voltage (Vcc).

According to the voltage supply method of the seventeenth aspect, the discrete voltages (Va0) can be switched depending on the voltage of the envelope signal (E1). This configuration reduces the loss.

According to the voltage supply method of the seventeenth aspect, no switching element is directly coupled to an element (the power amplifier 4, for example) on the output side. This configuration reduces switching noise leakage to elements on the output side.

What is claimed:

1. An analog ET circuit comprising:
an envelope amplifier configured to receive an envelope signal; and
a voltage supply unit configured to supply a plurality of discrete voltages to the envelope amplifier,
wherein the envelope amplifier is configured to receive the plurality of discrete voltages and output a continuous output voltage based on at least one of the plurality of discrete voltages.

2. The analog ET circuit according to claim 1, wherein the envelope amplifier includes:
an input terminal configured to receive the envelope signal,
an output terminal configured to output the continuous output voltage, and
a power supply terminal supplied with the plurality of discrete voltages.

3. The analog ET circuit according to claim 1, wherein the voltage supply unit includes a supply modulator configured to selectively output the at least one of the plurality of discrete voltages to the envelope amplifier.

4. The analog ET circuit according to claim 1, wherein the voltage supply unit includes:
a first voltage supply unit configured to supply a plurality of first discrete voltages to a high side of the envelope amplifier, and
a second voltage supply unit configured to supply a plurality of second discrete voltages to a low side of the envelope amplifier.

5. The analog ET circuit according to claim 4, wherein the envelope amplifier is further configured to receive the plurality of first discrete voltages, and the plurality of second discrete voltages.

6. The analog ET circuit according to claim 2, wherein the voltage supply unit includes:
a first voltage supply unit configured to supply a plurality of first discrete voltages to a high side of the envelope amplifier, and
a second voltage supply unit configured to supply a plurality of second discrete voltages to a low side of the envelope amplifier.

7. The analog ET circuit according to claim 6, wherein the power supply terminal includes:
a first power supply terminal supplied with the plurality of first discrete voltages, and
a second power supply terminal supplied with the plurality of second discrete voltages.

8. The analog ET circuit according to claim 1, wherein the envelope amplifier includes a plurality of amplification elements that are configured to be supplied with the plurality of discrete voltages from the voltage supply unit.

9. The analog ET circuit according to claim 1, further comprising a direct-current power source configured to supply a direct current to a path between the envelope amplifier and a power amplifier.

10. The analog ET circuit according to claim 9, wherein the direct-current power source includes a step-down converter configured to switch between a plurality of voltage levels.

11. The analog ET circuit according to claim 9, wherein the direct-current power source includes:
a switched-capacitor circuit configured to generate the plurality of discrete voltages,
a buck converter, and
an inductor coupled between the buck converter and the path.

12. The analog ET circuit according to claim 9, wherein the direct-current power source includes:
a switched-capacitor circuit configured to generate the plurality of discrete voltages,
a supply modulator configured to selectively output the plurality of discrete voltages, and
an inductor coupled between the supply modulator and the path.

13. The analog ET circuit according to claim 1, wherein the voltage supply unit includes a switched-capacitor circuit configured to generate the plurality of discrete voltages depending on an input voltage.

14. The analog ET circuit according to claim 1, wherein the voltage supply unit includes a DC-DC converter.

15. The analog ET circuit according to claim 1, further comprising:
a direct-current power source configured to supply a direct current to a path between the envelope amplifier and a power amplifier, the direct-current power source including:
a switched-capacitor circuit configured to generate a plurality of discrete voltages, and
a supply modulator configured to selectively output one of the plurality of discrete voltages, and
wherein the supply modulator of the direct-current power source is configured to adjust a duty ratio of a first discrete voltage and a second discrete voltage among the plurality of discrete voltages.

16. The analog ET circuit according to claim 1, further comprising:
a direct-current power source configured to supply a direct current to a path between the envelope amplifier and a power amplifier,
wherein the voltage supply unit includes:
a switched-capacitor circuit configured to generate the plurality of discrete voltages, and
a supply modulator configured to selectively output one of the plurality of discrete voltages to the envelope amplifier, and
wherein the direct-current power source includes a switched-capacitor circuit, and a supply modulator.

17. The analog ET circuit according to claim 16, wherein the switched-capacitor circuit of the voltage supply unit is integrated with the switched-capacitor circuit of the direct-current power source.

18. A radio-frequency system comprising:
the analog ET circuit according to claim 1; and
a power amplifier coupled to the analog ET circuit.

19. A communication device comprising:
the radio-frequency system according to claim 15; and
a signal processing circuit coupled to the radio-frequency system.

20. A voltage supply method comprising:
generating a plurality of discrete voltages in advance; and
receiving an envelope signal and the plurality of discrete voltages to output a continuous output voltage based on at least one of the plurality of discrete voltages.
